(19) United States
(12) Patent Application Publication
(10) Pub. No.: US 2013/0105200 A1
(43) Pub. Date: May 2, 2013

(54) PREPREG, WIRING BOARD, AND SEMICONDUCTOR DEVICE

(71) Applicants: Noriyuki Ohigashi, Tokyo (JP); Tadasuke Endo, Tokyo (JP)

(72) Inventors: Noriyuki Ohigashi, Tokyo (JP); Tadasuke Endo, Tokyo (JP)

(73) Assignee: SUMITOMO BAKELITE CO., LTD., Tokyo (JP)

(21) Appl. No.: 13/807,254

(22) PCT Filed: Jun. 29, 2011
(86) PCT No.: PCT/JP2011/064913

§ 371 Date: Dec. 27, 2012

(30) Foreign Application Priority Data
Jul. 1, 2010 (JP) 2010-151259

(51) Int. Cl. B32B 19/02; H05K 1/02

(52) U.S. Cl. CPC B32B 19/02; H05K 1/02
USPC 174/250; 428/325; 428/141; 428/213

(57) ABSTRACT

An object of the invention is to provide a prepreg which can be thinner, and has both surfaces which have different application, function, performance or properties to each other, one of which has excellent adhesion to the conductive layer, and the conductive layer which is in contact with the one surface of the prepreg can form a fine circuit, and the present invention provides a prepreg including a core layer containing a fibrous base, a first resin layer which is formed on one surface of the core layer, a second layer which is formed on the other surface of the core layer, and a carrier film which is selected from the group consisting of a metal foil and a resin film and which is laminated on at least one of the surfaces of the first resin layer and the second resin layer, wherein the first resin layer contains a first epoxy resin composition containing silica nanoparticles having an average particle diameter of 1 to 100 nm; a thermoplastic resin selected from the group consisting of a polyimide resin, a polyamide resin, a phenoxy resin, a polyphenylene oxide resin, and a polyether sulfone resin; and an epoxy resin, and the first resin layer is in contact with the fibrous base or a part of the first resin layer is infiltrated into the fibrous base; the second resin layer contains a second epoxy resin composition containing an inorganic filler, and an epoxy resin, and a part of the second resin layer is infiltrated into the fibrous base.

### TECHNICAL FIELD

The present invention relates to a prepreg, a wiring board, and a semiconductor device.

Priority is claimed on Japanese Patent Application No. 2010-151259 filed Jul. 1, 2010, the contents of which are incorporated herein by reference.

### BACKGROUND ART

A wiring board (circuit board) is generally produced by laminating plural prepregs which are produced by infiltrating a thermosetting resin into a glass fiber base, heating and applying pressure to them. The prepreg can be produced by a method in which a glass fiber base having a thickness of about 50 to about 200 μm, and the like is infiltrated into a thermosetting resin composition (varnish) (For example, Patent Document No. 1).

The prepreg is required to have an embeddability for embedding gaps of the circuit wirings at one surface, and an adhesion to a conductive layer for a circuit at the other surface. However, the prepreg, which is produced by a conventional method in which the glass fiber base and the like is infiltrated with a thermosetting resin composition, has both surfaces made of the same thermosetting resin composition. Due to this, a thermosetting resin composition which satisfies both properties has been used.

In addition, since recent electronic elements and electronic devices have become increasingly thinner and smaller, the wiring board used in them is also requested to be smaller and thinner. In order to respond to these demands, the prepreg constituting the wiring board is also required to be thinner. However, it is difficult to produce a prepreg which satisfies both embeddability and adhesion to the conductive layer in a case of being thinner. In addition, it is also difficult to produce a fine circuit board by laminating the conductive layer on the prepreg.

### BACKGROUND ART DOCUMENT

[Patent Document No. 1] Japanese Unexamined Patent Application, First Publication No. 2004-216784

### SUMMARY OF INVENTION

### Technical Problem

One object of the present invention is to provide a prepreg which can be thinner, and has both surfaces which have different application, function, performance or properties to each other, one of which has excellent adhesion to a conductive layer, and the conductive layer which is in contact with the one surface of the prepreg can form a fine circuit.

In addition, another object of the present invention is to provide a wiring board including the prepreg, and a semiconductor device including the wiring board.

### Means to Solve the Problems

These objects can be solved by the following inventions (1) to (13).

(1) A prepreg including a core layer containing a fibrous base, a first resin layer which is formed on one surface of the core layer, a second layer which is formed on the other surface of the core layer, and a carrier film which is selected from the group consisting of a metal foil and a resin film and which is laminated on at least one of the surfaces of the first resin layer and the second resin layer,

wherein the first resin layer contains a first epoxy resin composition containing silica nanoparticles having an average particle diameter of 1 to 100 nm; a thermoplastic resin selected from the group consisting of a polyimide resin, a polyamide resin, a phenoxy resin, a polyphenylene oxide resin, and a polyether sulfone resin; and an epoxy resin, and the first resin layer is in contact with the fibrous base or a part of the first resin layer is infiltrated into the fibrous base; and

the second resin layer contains a second epoxy resin composition containing an inorganic filler, and an epoxy resin, and a part of the second resin layer is infiltrated into the fibrous base.

(2) The prepreg according to (1), wherein the first epoxy resin composition contains 1 to 25% by weight of the silica nanoparticles having an average particle diameter of 1 to 100 nm.
(3) The prepreg according to (1) or (2), wherein the surface roughness (below, sometimes abbreviated as “Ra”) of the surface of the first resin layer which is not in contact with the fibrous base is 0.8 μm or less.
(4) The prepreg according to any one of (1) to (3), wherein the average particle diameter of the inorganic filler in the second epoxy resin composition is in a range of 0.3 to 3 μM.
(5) The prepreg according to any one of (1) to (4), wherein the second epoxy resin composition further contains a cyanate resin.
(6) The prepreg according to any one of (1) to (5), wherein the first resin layer is thinner than the second resin layer.
(7) The prepreg according to any one of (1) to (6), wherein the percentage of the thickness of the first resin layer is 5% or more and less than 40% of the total thickness of the core layer, the first resin layer, and the second resin layer.
(8) The prepreg according to any one of (1) to (7), wherein the total thickness of the core layer, the first resin layer, and the second resin layer is 120 μm or less.
(9) The prepreg according to any one of (1) to (8), wherein the thickness of the fibrous base is 100 μm or less.
(10) The prepreg according to any one of (1) to (9), wherein the melt viscosity of the second epoxy resin composition constituting the second resin layer is in a range of 50 to 5,000 Pa·s.
(11) The prepreg according to any one of (1) to (10), wherein the first epoxy resin composition further contains spherical silica having an average particle diameter in a range of 0.1 to 2 μm.
(12) A wiring board including the prepreg according to any one of (1) to (11) which is laminated on a conductive circuit such that the second resin layer is in contact with the conductive circuit.
(13) A semiconductor device including the wiring board according to (12).

### Advantageous Effects of Invention

According to the present invention, it is possible to produce a prepreg which is thinner, and has both surfaces having different applications, functions, performances, and properties. For example, it is possible to produce a prepreg including one surface which has excellent adhesion to a conductive layer, and make a fine circuit on the conductive layer laminated on the surface of the prepreg.

In addition, the wiring board and the semiconductor device, which are produced using the prepreg, have high reliability in insulation properties, connection, and mounting.

### BRIEF DESCRIPTION OF DRAWINGS

FIG. 1 is a cross-sectional view schematically illustrating one example of the prepreg according to the present invention

FIG. 2 is a cross-sectional view schematically illustrating the conditions in which the core layer of the prepreg according to the present invention locates non-uniformly in the thickness direction of the prepreg.

FIG. 3 is a cross-sectional view schematically illustrating one example of the wiring board according to the present invention.

FIG. 4 is a cross-sectional view schematically illustrating one example of the semiconductor device according to the present invention

### DESCRIPTION OF EMBODIMENTS

The prepreg according to the present invention is a prepreg including a core layer containing a fibrous base, a first resin layer which is formed on one surface of the core layer, a second layer which is formed on the other surface of the core layer, and a carrier film selected from the group consisting of a metal foil and a resin film which is laminated on at least one of the surfaces of the first resin layer and the second resin layer,

wherein the first resin layer contains a first epoxy resin composition containing silica nanoparticles having an average particle diameter of 1 to 100 nm, a thermoplastic resin selected from the group consisting of a polyimide resin, a polyamide resin, a phenoxy resin, a polyphenylene oxide resin, a polyether sulfone resin, and an epoxy resin; and the first resin layer is in contact with the fibrous base or a part of the first resin layer is infiltrated into the fibrous base; the second resin layer contains a second epoxy resin composition containing an inorganic filler, and an epoxy resin; and a part of the second resin layer is infiltrated into the fibrous base.

Below, the preferable embodiments of the prepreg according to the present invention are explained referring to figures.

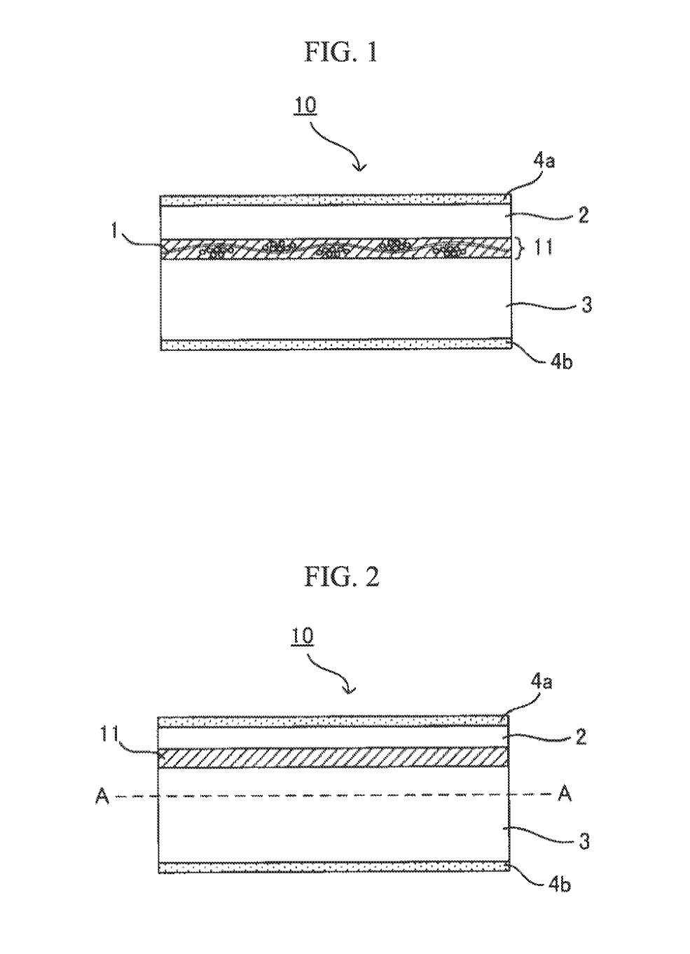

FIG. 1 is a cross-sectional view illustrating one example of the prepreg according to the present invention.

The prepreg 10 includes a core layer 11 which is formed mainly by a fibrous base 1, a first resin layer 2 which is formed on one surface of the core layer 2, a second layer 3 which is formed on the other surface of the core layer 2, a carrier film 4a which is laminated on the first resin layer 2, and a carrier film 4b which is laminated on the second resin layer 3.

A first epoxy resin composition constituting the first resin layer 2 and a second epoxy resin composition constituting the second resin layer 3 have different compositions to each other. Therefore, it is possible to satisfy properties which are desired for each layer. As a result, it is also possible to reduce the thickness of the prepreg while maintaining desired properties for each layer.

Below, each layer is explained.

(Core Layer)

The core layer 11 is formed mainly by the fibrous base 1. The core layer 11 improves the strength of the prepreg 10.

The core layer 11 is formed by infiltrating a part of the first resin layer 2 and/or the second resin layer 3 into the fibrous base 1.

Examples of the fibrous base 1 include a fibrous base, for example, a glass fibrous base, such as a glass woven fabric, and a glass non-woven fabric; a synthetic fibrous base made of a woven fabric or a non-woven fabric made of polyamide base resin fiber such as polyamide resin fiber, aromatic polyamide resin fiber, fully aromatic polyamide resin fiber, polyester-based resin fiber such as polyester resin fiber, aromatic polyester resin fiber, fully aromatic polyester resin fiber, polyimide resin fiber, and fluorine resin fiber; organic fibrous base such as a craft paper, a cotton linter, and a paper mainly made of mixed papermaking of linter and craft pulp; and a resin film such as a polyester film and a polyimide film. Among these, a glass fibrous base is preferable. It is possible to improve the strength of the prepreg 10 by using a glass fibrous base. It is also possible to decrease the coefficient of thermal expansion of the prepreg 10.

Examples of the glass constituting the glass fibrous base include E glass, C glass, A glass, S glass, D glass, NE glass, T glass, and H glass. Among these, S glass and T glass are preferable. It is possible to decrease the coefficient of thermal expansion of the glass fibrous base by using S glass or T glass, and thereby decrease the coefficient of thermal expansion of the prepreg.

The thickness of the fibrous base 1 is not particularly limited. However, the thickness of the fibrous base 1 is preferably 100 μm or less, and more preferably 5 to 60 μm in the present invention. When the thickness of the fibrous base 1 is in the range, it is possible to obtain high strength even when the base is thin, that is, good balance between the thickness and strength. In addition, workability and reliability in the connection of layers are also excellent.

[First Resin Layer]

As shown in FIG. 1, the first resin layer 2 is formed on one surface of the core layer 11 (in FIG. 1, the upper surface of the core layer 11).

The first resin layer 2 contains a first epoxy resin composition containing silica nanoparticles having an average particle diameter of 1 to 100 nm; a thermoplastic resin selected from the group consisting of a polyimide resin, a polyamide resin, a phenoxy resin, a polyphenylene oxide resin, and a polyether sulfone resin; and an epoxy resin The first resin layer 2 is in contact with the fibrous base 1. Otherwise, a part of the first resin layer 2, which is in contact with the fibrous base 1, is infiltrated into the fibrous base 1. In other words, a part of the first epoxy resin composition constituting the first resin layer is infiltrated into the fibrous base 1, and thereby producing the first resin layer 2. The first resin layer 2 is formed in particular so as to have high adhesion to a conductive layer. Therefore, it is possible to use the first resin layer 2 as a resin layer for laminating a conductive layer.

The first epoxy resin composition contains a thermoplastic resin selected from the group consisting of a polyimide resin, a polyamide resin, a phenoxy resin, a polyphenylene oxide resin, and a polyether sulfone resin. Due to this, flexibility and toughness are improved, and the adhesion between the conductive layer and the first resin layer made of the first epoxy resin composition can also be improved. In addition, since the solubility to the thermosetting resin such as epoxy resin is excellent, it is possible to form a uniform resin composition. Furthermore, when cyanate resin is used as the thermosetting resin, curability is further improved due to the effects obtained by the polar groups in the thermoplastic resin than in a case of using only cyanate resin. In addition, mechanical strength is also improved.

Any polyimide resins can be used without limitations. For example, it is possible to use polyimide resin which is produced by dehydration synthesis using well-known tetracarboxylic dianhydrate and diamine as raw materials. Among these, it is preferable to use the polyimide resin which is produced by using tetracarboxylic dianhydrate and diisocyanate, and has the following structure formula (1).

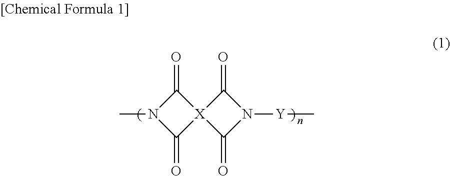

(in the formula, X represents a molecular structure originated by tetracarboxylic dihydrate, and Y represents a molecular structure originated by diamine or diisocyanate.)

Among these, it is preferable to use silicone-modified polyimide resin represented by the following structure formula (2), because it can be dissolved in a solvent, and a uniform composition can be produced.

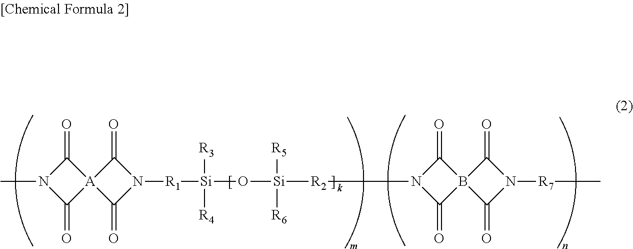

(in the formula, R₁ and R₂ represent a divalent aliphatic or aromatic group having 1 to 4 carbon atoms, R₃, R₄, R₅, and R₆ represent a monovalent aliphatic or aromatic group, A and B represent a trivalent or tetravalent aliphatic or aromatic group, R₇ represents a divalent aliphatic or aromatic group, and k, m and n represent the number of a repeating unit, and an integer of 5 to 5,000.)

In addition, polyamideimide resin having an amide structure in a polyimide block is also preferable because it can be dissolved in a solvent.

Any polyamide resins can be used without limitation. However, the polyamide resin which is represented by the following structure formula (3) is preferably used.

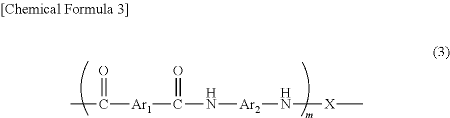

(in the formula, Ar₁ and Ar₂ represent a divalent hydrocarbon or aromatic group, and may be different in repeating unit, X represents a terminal group which is additionally reacted to the terminal, and m represents the number of a repeating unit, and an integer of 5 to 5,000.)

Among these, rubber-modified polyamide resin is preferable. When the rubber-modified polyamide resin is used, flexibility of the first resin layer is improved, and thereby, the adhesion to the conductive layer is also improved. Examples of the rubber-modified polyamide resin include the product which is obtained by reacting a rubber component as X in the structure formula (3).

As the rubber component which reacts with the polyamide resin, natural rubber or synthetic rubber can be used, and modified rubber or unmodified rubber can also be used.

Any synthetic rubbers can be used, and examples of the synthetic rubber include NBR (nitrile rubber), acryl rubber, polybutadiene, isoprene, carbonic acid-modified NBR, hydrogenated polybutadiene, and epoxy-modified polybutadiene. In order to improve the solubility to the polyamideimide, carboxylic-modified rubber, hydroxyl group-modified rubber, epoxy-modified rubber can be used. In order to prevent the thermal degradation, hydrogen-added synthetic rubber can also be used. However, NBR or polybutadiene is preferably used. In addition, polyamide resin having a phenolic hydroxyl group is more preferable. When polyamide resin having a phenolic hydroxyl group is used, the first resin layer having flexibility can be produced. In addition, the polyamide resin having a phenolic hydroxyl group has excellent compatibility to the thermosetting resin and can form three-dimensional cross-linking with the polyamide polymer by thermal setting. Due to this, it is possible to produce the first resin layer having excellent mechanical strength. Specifically, the polyamide resin represented by the following structure formula (4) can be preferably used.

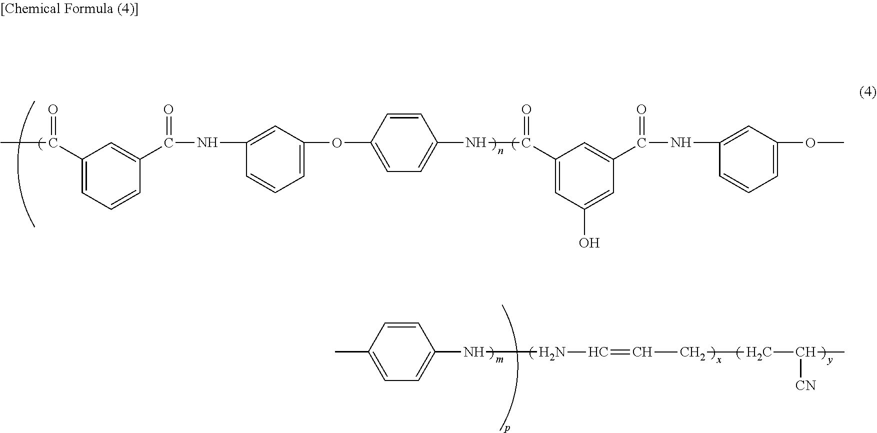

(in the formula, n and m represent a charged molar ratio, n/(m+n)=0.05 to 2 (charged molar ratio), x, y, and p represent a weight ratio, (x+y)/p=0.2 to 2 (weight ratio), weight average molecular weight is 8,000 to 100,000, and hydroxyl equivalent is 1,000 to 5,000 g/eq.)

Any phenoxy resins can be used. Examples of the phenoxy resin include phenoxy resin having a bisphenol structure, phenoxy resin having a naphthalene structure, phenoxy resin having a biphenyl structure, and phenoxy resin having a bisphenol acetone structure. In addition, it is also possible to use phenoxy resin having plural of these structures. Among these, phenoxy resin having two or more of a structure selected from a biphenyl structure, bisphenol S structure, and bisphenol acetone structure is preferable. When the phenoxy resin is used, the glass transition point can be improved. In addition, when the phenoxy resin has a biphenyl structure, since a biphenyl structure has rigidity, the first resin layer having low thermal expansion properties can be used. Furthermore, when the phenoxy resin has a bisphenol S structure, adhesion to plated metal can be improved during manufacture of the wiring board.

In addition, phenoxy resin having a bisphenol A structure and a bisphenol F structure is also preferable. When the phenoxy resin is used, it is possible to further improve the adhesion of the prepreg to the inner layer circuit board during manufacturing of the wiring board.

Any polyphenylene oxide resins can be used without limitation. However, the polyphenylene oxide resin represented by the following structure formula (5) is preferable.

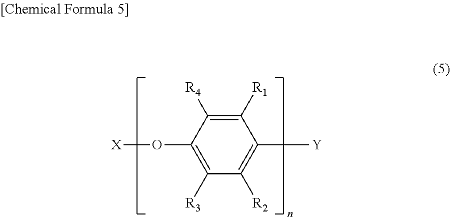

(in the formula, n represents the number of a repeating unit, and an integer of 10 to 400, R₁, R₂, R₃, and R₄, represent a hydrogen atom, or a hydrocarbon group having 1 to 6 carbon atoms, and may be the same or not, X and Y represent a terminal group, and a hydrogen atom, hydrocarbon or a functional group such as a hydroxyl group, a carboxyl group, a glycidyl ether group, or the like.)

Examples of the polyphenylene oxide resin include poly(2, 6-dimethyl-1,4-phenylene)oxide, poly(2,6-diethyl-1,4-phenylene)oxide, poly(2-methyl-6-ethyl-1,4-phenylene)oxide, poly(2-methyl-6-propyl-1,4-phenylene)oxide, poly(2,6-dipropyl-1,4-phenylene)oxide, and poly(2-ethyl-6-propyl-1,4-phenylene)oxide.

Among these, reactive oligophenylene oxide of which the terminal is modified with a functional group is preferable. When the reactive oligophenylene oxide is used, the compatibility to the thermosetting resin can be improved. In addition, since three-dimensional cross-linking can be formed in the polymer, the mechanical strength of the prepreg can also be improved. Examples of the reactive oligophenylene oxide include a reaction product between 2,2′,3,3′5,5′-hexamethylbiphenyl-4,4′-diol-2,6-dimethyl phenol polycondensate and chloromethyl styrene.

Such reactive oligophenylene oxide can be produced by a well-known method. In addition, commercialized products can also be used. Specifically, OPE-2st 2200 (produced by Mitsubishi Gas Chemical Company) can be preferably used.

The weight average molecular weight of the reactive oligophenylene oxide is preferably 2,000 to 20,000, and more preferably 4,000 to 15,000. When the weight average molecular weight of the reactive oligophenylene oxide exceeds 20,000, the reactive oligophenylene oxide may be hardly dissolved in a volatile solvent. In contrast, when the weight average molecular weight of the reactive oligophenylene oxide is less than 2,000, the density of cross-linking is too high, and adverse effects may be caused in modulus elasticity and flexibility of the cured product.

Any polyethersulfone resins can be used in the present invention without limitation. However, the polyethersulfone resin represented by the following structure formula (6) is preferably used.

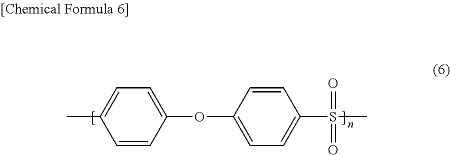

(in the formula, n represents the number of the repeating unit.)

Well-known polyethersulfone resins can be used as the polyethersulfone resin represented by the structure formula (6). For example, PES4100P, PES4800P, PES5003P, or EPS5200P, which is produced by Sumitomo Chemical Co., Ltd., can be used.

Among thermoplastic resins which are selected from the group consisting of polyimide resin, polyamide resin, phenoxy resin, polyphenylene oxide resin, and polyethersulfone resin, in particular, polyamide resin and phenoxy resin are preferable. Polyamide resin and phenoxy resin are easily dissolved in a solvent, and therefore handling is easy. In addition, polyamide resin and phenoxy resin have reactive cross-linking points to the thermosetting resin. Due to this, the obtained cured product has excellent mechanical strength. The first resin layer obtained has high adhesion to the conductive layer.

The content of the thermoplastic resin is not particularly limited. However, the content of the thermoplastic resin relative to 100% by weight of the solid compounds in the first epoxy resin composition is preferably 10 to 70% by weight, and more preferably 20 to 50% by weight. When the content of the thermoplastic resin is less than 10% by weight, flexibility and mechanical strength tend to be decreased. In contrast, when the content of the thermoplastic resin exceeds 70% by weight, the coefficient of thermal expansion tends to be high. By adjusting the content of the thermoplastic resin to be in the range, the prepreg having good balance between these properties can be obtained.

The glass transition temperature of the thermoplastic resin is preferably 110 to 280° C. When the glass transition temperature of the thermoplastic resin is in the range, the first epoxy resin composition having excellent thermal resistance, and compatibility to the thermosetting resin can be obtained. Due to this, the first resin layer obtained has excellent adhesion to the core layer.

In addition, the weight average molecular weight of the thermoplastic resin is preferably 2,000 to 100,000. When the weight average molecular weight of the thermoplastic resin is in the range, the thermoplastic resin has high solubility to a solvent and compatibility to the thermosetting resin.

In addition, the first epoxy resin composition further contains an epoxy resin.

Any epoxy resins can be used without limitation. However, the epoxy resin is an epoxy resin which does not practically contain a halogen atom. Examples of the epoxy resin in the first epoxy resin composition include bisphenol type epoxy resin, such as bisphenol A type epoxy resin, bisphenol F type epoxy resin, bisphenol E type epoxy resin, bisphenol S type epoxy resin, bisphenol Z type epoxy resin, bisphenol P type epoxy resin, and bisphenol M type epoxy resin; novolac type epoxy resin, such as phenol novolac type epoxy resin and cresol novolac type epoxy resin; arylalkylene type epoxy resin such as biphenyl type epoxy resin, xylene type epoxy resin, phenol aralkyl type epoxy resin, biphenyl aralkyl type epoxy resin, biphenyl dimethylene type epoxy resin, trisphenolmethane novolac type epoxy resin, glycidyl ethers of 1,1,2,2-(tetraphenol)ethane, trifunctional or tetrafunctional glycidylamines, and tetramethyl biphenyl type epoxy resin; naphthalene type epoxy resin such as naphthalene skeleton-modified cresol novolac type epoxy resin, methoxynaphtalene-modified cresol novolac type epoxy resin, methoxynaphthalene dimethylene type epoxy resin, and naphtholalkylene type epoxy resin; anthracene type epoxy resin; phenoxy type epoxy resin; dicyclopentadiene type epoxy resin; norbornene type epoxy resin; adamantine type epoxy resin; fluorine type epoxy resin; and halogenated thereof having flame resistance. These epoxy resins can be used alone. In addition, two or more kinds of the epoxy resins having different weight average molecular weight can be combined. Furthermore, one or more kinds of these epoxy resins and a prepolymer thereof can also be combined.

Among these epoxy resins, at least one epoxy resin selected from the group consisting of biphenylaralkyl type epoxy resin, naphthalene skeleton-modified cresol novolac type epoxy resin, anthracene type epoxy resin, dicyclopentadiene type epoxy resin, cresol novolac type epoxy resin, and naphthalene type epoxy resin is preferably used.

When the epoxy resin is used, low water absorbability and flame resistance are further improved.

The content of the epoxy resin is not particularly limited. However, the content of the epoxy resin in the total solid contents in the first epoxy resin composition is preferably in a range of 5 to 70% by weight, and more preferably in a range of 15 to 60% by weight. When the content is less than 5% by weight, reactivity of the isocyanate resin or moisture resistance of the obtained prepreg may be decreased. In contrast, when the content exceeds 70% by weight, heat resistance may be decreased.

The weight average molecular weight of the epoxy resin is not particularly limited. However, the weight average molecular weight of the epoxy resin is preferably in a range of 300 to 20,000, and more preferably in a range of 500 to 5,000. When the weight average molecular weight of the epoxy resin is less than 300, the obtained prepreg 10 may have stickiness. In contrast, when the weight average molecular weight exceeds 20,000, the first epoxy resin composition is not readily infiltrated into the fibrous base, and the prepreg having a uniform thickness may not be obtained.

For example, the weight average molecular weight of the epoxy resin can be measured by Gel Permeation Chromatography (GPC), and specified as a weight molecular weight in terms of polystyrene standard.

The first epoxy resin composition can contain a curing agent in the present invention.

Any curing agents can be used. Examples of the curing agent include organic metal salts such as zinc naphthate, cobalt naphthate, tin octylate, cobalt octylate, bis(acetylacetonate) cobalt (II), and tris(acetylacetonate) cobalt (III); phenol compounds such as phenol, bisphenol A, and nonylphenol; organic acids such as acetic acid, benzoic acid, salicylic acid, paratoluenesulfonic acid; tertiary amines such as triethylamine, tributylamine, diazocyclo[2,2,2]octane; and imidazole-based compounds such as 2-ethyl-4-ethylimidazole, 2-phenyl-4-methylimidazole, 2-phenyl-4-methyl-5-hydroxymethylimidazole, 2-phenyl-4,5-dihydroxymethylimidazole, 2,4-diamino-6-[2′-methylimidazoryl-(1′)]-ethyl-s-triazine, 2,4-diamino-6-(2′-undecylimidazoryl)-ethyl-s-triazine, 2,4-diamino-6-[2′-ethyl-4-methylimidazoryl-(1′)]ethyl-s-triazine, and 1-benzyl-2-phenylimidazol.

Among these curing agents, from the viewpoint of adhesion to the conductive layer, tertiary amines and imidazole-based compounds are preferable, imidazole-based compounds having at least two groups selected from the group consisting of an aliphatic hydrocarbon group, an aromatic hydrocarbon group, a hydroxyalkyl group, and cyanoalkyl are more preferable, and 2-phenyl-4,5-dihydroxymethylimidazole is most preferable. By using the imidazole-based compound, it is possible to improve the adhesion to the conductive layer, as well as heat resistance of the first epoxy resin composition. In addition, when the first epoxy resin composition containing the imidazole-based compound is used, the first resin layer having low thermal expansion characteristics and low moisture absorbency can be produced.

The content of the curing agent is not particularly limited. However, the content of the curing agent in the solid contents of the first epoxy resin composition is preferably in a range of 0.01 to 3% by weight, and more preferably in a range of 0.1 to 1% by weight. When the content is less than 0.01% by weight, curing may be promoted. In contrast, when the content exceeds 3% by weight, the storage ability of the obtained prepreg may be deteriorated.

In addition, the first epoxy resin composition contains silica nanoparticles in the present invention. It is possible to improve the strength and low thermal expansion characteristics of the prepreg by containing silica nanoparticles even when the prepreg is thin (the thickness is 120 μm or less). In addition, the first resin layer obtained has excellent adhesion to the plated copper produced by an additive method, and a fine circuit can be produced. Furthermore, since the obtained prepreg has high chemical resistance, it is possible to form a rough surface having low Ra by treating the first resin layer with permanganic acid or the like. Moreover, “Ra” means an arithmetic means roughness, and can be calculated in accordance with JIS B0601.

The average particle diameter of the silica nanoparticles is preferably in a range of 1 to 100 nm, and more preferably in a range of 25 to 75 nm. When the average particle diameter is in the range, the silica nanoparticles have excellent dispersibility, and a rough surface having low Ra can be produced.

The average particle diameter of the silica nanoparticles can be measured by a laser diffraction method. Specifically, the silica nanoparticles are dispersed in water by ultrasonic wave, the particle size distribution of the silica nanoparticles is measured in terms of volume standard using a dynamic light scattering type particle size distribution measuring instrument (HORIBA ltd.; LB-550), and the median diameter (D50) is defined as the average particle diameter.

Any silica nanoparticles can be used without limitations. However, silica nanoparticles which are produced by a combustion method, such as a VMC method (Vaporized Metal Combustion method), and PVS method (Physical Vapor Synthesis) method, a melt method in which crushed silica is melted by flame, a precipitation method, a gel method, and the like, can be used. Among these, the silica nanoparticles obtained by a VMC method are preferable. The VMC method is a method for producing silica fine particles in which silicon powder is put into a chemical flame formed in an oxygen-containing gas, combusted, and then cooled. In the VMC method, it is possible to control the particle diameter of the produced silica nanoparticles by adjusting the diameter of the silicon powder and the amount of silica powder, which is put into the flame, or the temperature of the flame.

In addition, commercialized silica nanoparticles, such as NSS-5N (Tokuyama Corporation), Sicastar 43-00-501 (Micromod) can also be used.

The content of the silica nanoparticles is not particularly limited. However, the content of the silica nanoparticles in the solid contents of the first epoxy resin composition is preferably in a range of 1 to 25% by weight, more preferably in a range of 1 to 16% by weight, and most preferably in a range of 2 to 10% by weight. When the content of the silica nanoparticles is in the range, the silica nanoparticles are sufficiently dispersed and therefore, the adhesion to the conductive layer is increased, and a rough surface having low Ra can be produced.

It is preferable that the first epoxy resin composition contain spherical silica together with the silica nanoparticles. When the first epoxy resin composition contains the silica nanoparticles and spherical silica, filling properties of the silica nanoparticles and spherical silica can be improved. In addition, dense rough conditions can be produced, and a high density circuit can be easily produced. In addition, a circuit suitable for transferring high-speed signals can be produced. Furthermore, low thermal expansion properties, flowability of the first resin layer, and laminate properties to the glass cloth can also be improved.

The average particle diameter of the spherical silica is preferably in a range of 0.1 to 2 μm, and more preferably in a range of 0.1 to 5 μm. When the average particle diameter of the spherical silica is in the range, the first resin layer having a rough surface with low Ra can be obtained, the spherical silica is uniformly dispersed in the first resin layer, and the handling thereof is easy.

Similar to the silica nanoparticles, the average particle diameter of the spherical silica is defined by measuring the particle size distribution of the silica nanoparticles in terms of volume standard using a dynamic light scattering type particle size distribution measuring instrument (HORIBA ltd.; LA-500), and the median diameter (D50) is defined as the average particle diameter.

The content of the spherical silica is not particularly limited. However, the content of the spherical silica in the solid contents of the first epoxy resin composition is preferably in a range of 1 to 50% by weight, and more preferably in a range of 2 to 20% by weight. When the content of the spherical silica is in the range, since the dispersibility is improved, the obtained prepreg has a rough surface with low Ra, and adhesion to the conductive layer is excellent.

The first epoxy resin composition can also contain inorganic fillers such as boehmite, talc, alumina, glass, mica, aluminum hydroxide, magnesium hydroxide, calcium carbonate, zinc oxide, and iron oxides, as long as they do not deteriorate the properties of the prepreg. It is also possible to contain organic fillers such as liquid crystal polymer, polyimide together with the inorganic filler.

It is preferable that the first epoxy resin composition contain a coupling agent. Any coupling agent can be used. The coupling agent improves wettability of the interface between the curable resin and the inorganic filler, thereby making the curable resin and the inorganic filler uniformly fix to the fibrous base 1. Due to this, it is possible to improve heat resistance of the prepreg, in particular, solder-heat resistance after absorbing moisture.

It is preferable to use at least one selected from the group consisting of an epoxysilane coupling agent, a titanate-based coupling agent, an aminosilane coupling agent, and a silicone oil type coupling agent as the coupling agent. Thereby, it is possible to improve the wettability of the interface between the resin and the inorganic tiller. Due to this, heat resistance of the prepreg can be further improved.

The content of the coupling agent is not particularly limited. However, the content of the coupling agent in the solid contents of the first epoxy resin composition is preferably in a range of 0.04 to 3.75% by weight, and more preferably in a range of 0.04 to 1.50% by weight. When the content of the coupling agent is less than 0.04% by weight, since the inorganic filler cannot be fully coated, the heat resistance may not be sufficiently improved. In contrast, when the content of the coupling agent exceeds 3.75% by weight, the coupling agent may cause adverse effects on reaction. Therefore, the bending strength or the like of the prepreg may be decreased. When the content of the coupling agent is adjusted to the range, the balance between the reaction and the bending strength is excellent in the prepreg.

In addition, the first epoxy resin composition may contain a curable resin such as urea resin, melamine resin, bismaleimide resin, polyurethane resin, and resin having a benzoxazine ring as long as it does not affect the properties of the prepreg, in addition to the thermoplastic resin, and the epoxy resin.

Furthermore, the first epoxy resin composition may contain additives such as an antifoaming agent, leveling agent, pigment, and oxidation inhibitor, and various kinds of solvents, if necessary, in addition to the components explained above.

In the wiring board according to the present invention, a conductive circuit is formed on the first resin layer made of the first epoxy resin composition by a well-known method such as an additive method. In this case, it is preferable that the first resin layer have peel strength to the conductive circuit of 0.5 kN/m or more, and more preferably 0.6 kN/m or more. When the peel strength of the first resin layer is less than 0.5 kN/m, the adhesion to the conductive circuit is poor and fine processing is difficult.

The surface roughness, Ra (arithmetic means roughness, JIS B0601) of the first resin layer (after roughening treatment) which is not in contact with the fibrous base 1 is not particularly limited. However, the surface roughness at the surface of the first resin layer which is not in contact with the fibrous base 1 is preferably 0.8 μm or less, and more preferably 0.5 μm or less. When the surface roughness is in the range, resist adhesion is excellent when a fine circuit is formed.

The melt viscosity of the first epoxy resin composition for the first resin layer is preferably in a range of 1,000 to 50,000 Pa·s, and more preferably in a range of 1,500 to 20,000 Pa·s. When the melt viscosity is in the range, the fibrous base is not exposed when laminating. In addition, after the prepreg of the present invention is laminated, it is possible to suppress partial separation of the prepreg and unevenness of the prepreg surface, which is caused along spaces between threads after curing with no load.

Moreover, the melt viscosity is a melt viscosity of the first resin layer when the first resin layer is taken out from the prepreg. At this time, the first resin layer may be semi-cured (B stage) or cured.

(Second Resin Layer)

As shown in FIG. 1, the second resin layer 3 is formed on the other surface of the core layer 11 (in FIG. 1, lower surface).

The second resin layer 3 is made of a second epoxy resin composition containing an inorganic filler, an epoxy resin, and the second epoxy resin composition is partially infiltrated into the fibrous base 1 which is in contact with the fibrous base 1. In other words, a part of the second epoxy resin composition is infiltrated into the fibrous base 1 to form the second resin layer.

The second epoxy resin composition constituting the second resin layer 3 has a different composition from that of the first epoxy resin composition constituting the first resin layer. That is, the second resin layer 3 is formed so as to have different characteristics such as embeddability of a circuit from those of the first resin layer 2.

Here, the term different resin composition means that there is at least one different in the first and second epoxy resin compositions, such as the kind of the resin or filler used in the resin compositions, the content of the resins or fillers, and the molecular weight of the resins.

In the second epoxy resin composition, the epoxy resin used in the first epoxy resin composition can be used.

The content of the epoxy resin is not particularly limited. However, the content of the epoxy resin in the solid contents in the second epoxy resin composition is preferably in a range of 1 to 50% by weight, and more preferably in a range of 5 to 30% by weight. When the content is in the range, circuit-embeddability is excellent and moisture absorbency is low.

In addition, it is preferable that the second epoxy resin composition contain cyanate resin. When the second epoxy resin composition contains cyanate resin, the coefficient of thermal expansion of the prepreg can be reduced. In addition, it is also possible to improve electrical properties, that is, to reduce the dielectric constant, and dielectric tangent. Furthermore, it is also possible to improve, heat resistance, rigidity, and adhesion to the conductive circuit of the prepreg.

The cyanate resin can be produced by reacting a halogenated cyanide compound with phenol, and pre-polymerizing by heating, and the like, if necessary.

Examples of the cyanate resin include naphthalene type cyanate resins such as novolac type cyanate resin, and alkylenenaphthol type cyanate resin; and bisphenol type cyanate resins such as bisphenol A type cyanate resin, bisphenol E type cyanate resin, tetramethyl bisphenol F type cyanate resin. Among these, polyfunctional cyanate resin having a large cyanate equivalent, such as novolac type cyanate resin and naphthalene type cyanate resin, is preferable. When the polyfunctional cyanate resin having a large cyanate equivalent is used, it is possible to improve the heat resistance due to an increase of the cross-linking density, and the flame resistance of the second epoxy resin composition. Since the novolac type cyanate resin forms a triazine ring after the curing reaction, these effects can be obtained. In addition, a percentage of the benzene ring in the novolac type cyanate resin is high, therefore, it is easily carbonized. From this point of view, it is believed that these effects can be obtained. Furthermore, even when the prepreg is thin such that the thickness thereof is adjusted to 120 μm or less, it is possible to make the prepreg have excellent rigidity. In particular, when the prepreg is heated, since the prepreg has excellent rigidity, the reliability is also excellent when mounting the semiconductor device.

As the novolac type cyanate resin, the novolac type cyanate resin represented by the following structure formula (7) can be used.

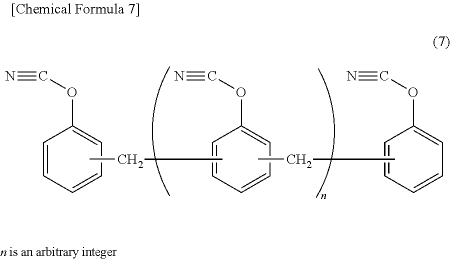

“n”, which represents an average number of the repeating unit in the novolac type cyanate resin represented by the structure formula, is not particularly limited. However, n is preferably an integer of 1 to 10, and more preferably in a range of 2 to 7.

When the average number of the repeating unit, n, is less than 1, the novolac type cyanate is easily crystallized, the solubility in a general solution is relatively low, and handling is difficult. In contrast, when the average number of the repeating unit, n, exceeds 10, the melt viscosity is too high, and moldability of the prepreg may be decreased.

The weight average molecular weight of the cyanate resin is not particularly limited. However, the weight average molecular weight of the cyanate resin is preferably in a range of 500 to 4,500, and more preferably in a range of 600 to 3,000. When the weight average molecular weight of the cyanate resin is less than 500, the prepreg obtained may have stickiness. Due to this, when the prepregs are in contact with each other, they may be adhered, or the resin layer may be transferred to the other resin layer. In contrast when the weight average molecular weight of the cyanate resin exceeds 4,500, reaction proceeds too fast. Due to this, when a wiring board is made using the prepreg, imperfect molding may be caused, or peeling strength between laminates may be decreased.

The weight average molecular weight of the cyanate resin or the like can be measured by Gel Permeation Chromatography (GPC), and specified as a weight molecular weight in terms of polystyrene standard.

In addition, as the cyanate resin, cyanate resins having different weight average molecular weight can be used at the same time. Thereby, the stickiness may be decreased.

As the cyanate resin, pre-polymerized cyanate resin can also be used.

In other words, the cyanate resin can be used alone or the cyanate resins having different weight average molecular weight to each other can be used at the same time, or the cyanate resin and the prepolymer thereof can be used at the same time.

The prepolymer can be obtained generally by a heating reaction of the cyanate resin, for example, by trimerization of the cyanate resin. The prepolymer is used to adjust the moldability or flowability of the resin composition.

The content of the cyanate resin is not particularly limited. However, the content of the cyanate resin in the solid contents of the second epoxy resin composition is preferably in a range of 1 to 45% by weight, and more preferably in a range of 5 to 30% by weight. When the content of the cyanate resin is less than 1% by weight, the coefficient of thermal expansion of an insulating layer including the prepreg 10 may be increased. In contrast, when the content of the cyanate resin exceeds 45% by weight, moisture absorbency may be increased, and heat resistance and mechanical strength may be decreased.

It is preferable that the second epoxy resin composition contain an inorganic filler. When the second epoxy resin composition contains an inorganic filler, even when the prepreg 10 is thinner, for example, the thickness of the prepreg is 120 μm or less, excellent strength can be obtained. In addition, it is also possible to further improve the low thermal expansibility.

Examples of the inorganic filler include boehmite, talc, alumina, glass, mica, aluminum hydroxide, and magnesium hydroxide. Among these, silica is preferably used, and melt silica, in particular, spherical melt silica, is more preferably used because of having low thermal expansibility. The shape of the inorganic filler may be a granular shape or spherical shape. In order to decrease the melt viscosity of the second epoxy resin composition and maintain infiltration properties of the second epoxy resin composition into the fibrous base 1, for example, spherical silica is used. Any suitable usage methods can be selected depending on the object.

The average particle diameter of the inorganic filler is preferably in a range of 0.3 to 3 μm, and more preferably in a range of 0.3 to 1.5 μm. When the average particle diameter of the inorganic filler is less than 0.3 μm, the melt viscosity of the second epoxy resin composition is increased, therefore, embeddability of the prepreg 10 obtained to the conductive circuit may be decreased. In contrast, when the average particle diameter of the inorganic filler exceeds 1.5 μm, and the second epoxy resin composition is dissolved or dispersed into a solvent, the inorganic filler may be precipitated, and a uniform resin layer may not be readily formed. In addition, when L/S of the conductive circuit of the inner substrate is less than 20 μm/20 μm, insulating properties between the wirings may be influenced.

The average particle diameter of the inorganic filler is a median diameter (D50) which is obtained by measuring particle distribution in terms of volume standard using a laser diffraction type particle size distribution measuring instrument (HORIBA ltd.; LA-500).

The content of the inorganic filler is not particularly limited. However, the content of the inorganic filler in the solid contents of the second epoxy resin composition is preferably in a range of 50 to 85% by weight, and more preferably in a range of 60 to 75% by weight. When the content of the inorganic filler is in the range, the dispersibility of the inorganic filler is excellent, and the infiltration properties of the second epoxy resin composition are also excellent. Due to this, embeddability to the conductive circuit is improved.

Furthermore, the second epoxy resin composition can contain additives such as an antifoaming agent, leveling agent, pigment, and oxidation inhibitor, and various kinds of solvents, if necessary, in addition to the components explained above.

The melt viscosity of the second epoxy resin composition constituting the second resin layer is preferably in a range of 50 to 5,000 Pa·s, and more preferably in a range of 100 to 2,000 Pa·s. When the melt viscosity is in the range, the embeddability is excellent, and the generation of molding lines (phenomenon in which only a resin component flows) can be prevented during laminating.

Moreover, the melt viscosity is a melt viscosity of the second resin layer when the second resin layer is taken out from the prepreg. At this time, the second resin layer may be semi-cured (B stage) or cured.

Below, a method for producing the prepreg according to the present invention is explained referring to the prepreg 10 shown in FIG. 1.

In order to produce the prepreg 1, for example, a first carrier material is produced by coating the first epoxy resin composition on a carrier film 4a. A second carrier material is also produced by coating the second epoxy resin composition on a carrier film 4b. After that, the first and second carrier materials obtained are laminated on the fibrous base 1. Thereby, the prepreg, in which the carrier film 4a is laminated on the surface of the first resin layer 2 and the carrier film and 4b is laminated on the surface of the second resin layer 3, can be produced.

Moreover, the prepreg according to the present invention is not limited to the embodiment in which the carrier films are laminated on the first resin layer 2 and the second resin layer 3, similar to the prepreg 10. The prepreg according to the present invention includes the prepreg in which the carrier film is laminated on at least one of the first resin layer 2 and the second resin layer 3.

The carrier film is selected from the group consisting of a metal foil and a resin film. Examples of the metal foil include metal foils such as a copper foil, and an aluminum foil; and a copper thin film which is produced by plating copper on a substrate. Among these, the metal foil and a copper thin film which is obtained by plating copper on a resin film as a substrate are preferable. When the metal foil or the copper thin film is used, a fine circuit can be easily produced.

Examples of the resin film include a polyolefin film such as a polyethylene film and a propylene film; a polyester film such as a polyethylene terephthalate film, and a polybutylene terephthalate film; a release paper such as a polycarbonate sheet and a silicone sheet, and a thermoplastic resin film having heat resistance such as a fluorine-based resin film, and a polyimide resin film. Among these, a polyester film is preferable. When the polyester film is used, the prepreg can be easily peeled from the conductive layer with appropriate strength.

The carrier film 4a in the first carrier material is not particularly limited. However, a copper thin sheet which is produced by plating copper on the substrate is preferable. The copper thin sheet can be used as a part of the conductive circuit. Otherwise, the total copper thin sheet can be etched by a semi-additive method to produce a conductive circuit.

The carrier film 4b in the second carrier material is also particularly limited. However, the resin film explained above is preferably used. During storing the prepreg, the resin film protects the second resin layer which becomes a circuit buried layer. When the wiring board is produced using the prepreg, the resin film can be peeled from the second resin layer with an appropriate strength.

As a method for laminating the first and second carrier material on the fibrous base 1, for example, a method is used in which the first carrier material is superimposed on one surface of the fibrous base 1 and the second carrier material is also superimposed on the other surface of the fibrous base 1, using a vacuum lamination device, the laminate produced is adhered closely using a lamination roller under reduced pressure, then the laminate is heated to the melt temperature, and the resin composition constituting the first and second carrier material is melted using a hot wind dryer. At this time, since the inside of the fibrous base is under reduced pressure, the resin composition can be melted and infiltrated into the fibrous base due to a capillary phenomenon. As a heating device other than a hot wind dryer, an infrared light heating device, heating roller, or a flat hot board presser can also be used.

In addition, as another method for producing the prepreg 10, a method can be used in which the first epoxy resin composition is infiltrated into one surface of the fibrous base 1, dried, and the carrier film 4a is superimposed thereon; and the second epoxy resin composition is infiltrated into the other surface of the fibrous base 1 and dried, and the carrier film 4a is superimposed thereon; and the laminate is heated and pressurized.

Furthermore, as other methods for producing the prepreg 10, the following can be used: (1) a method in which the first epoxy resin composition which becomes the first resin layer 2 is coated on the surface of the fibrous base 1, the first epoxy resin composition is infiltrated into the fibrous base 1 and dried, the second epoxy resin composition which becomes the second resin layer 3 is coated on the other surface of the fibrous base 1 using a roll coater, a comma coater, or the like, and dried to produce B-stage, the carrier films 4a and 4b are superimposed respectively on the resin composition under B-stage which becomes the second resin layer, and the resin composition layer which becomes the first resin layer, and they are laminated under heating and pressurized conditions; (2) a method in which the first epoxy resin composition is coated on and infiltrated into the fibrous base 1, and dried, the carrier film 4a is superimposed on the first epoxy resin composition which becomes the first resin layer, a B-stage resin composition, which becomes the second resin layer, including the carrier film 4b is formed separately, the laminate including the carrier film 4a is superimposed on the B-stage resin composition including the carrier film 4b, and they are laminated under heating and reduced pressure.

In the prepreg 10 produced in this way, as shown in FIG. 2, the core layer 11, which is mainly formed of the fibrous base 1, is deflected to one side of the prepreg 10 in the thickness direction of the prepreg 10. Due to this, the amount of the resin of the first resin layer 2 and the second resin layer 3 can be adjusted depending on the circuit pattern. Moreover, “the core layer 11 is deflected to one side of the prepreg in the thickness direction thereof” means, as shown in FIG. 2, the center line of the core layer 11 is misaligned with the center line A-A of the prepreg 10 in the thickness direction of the prepreg 10.

It is preferable that the first resin layer be thinner than the second resin layer in the prepreg according to the present invention.

In addition, it is also preferable that the percentage of thickness of the first resin layer relative to the thickness of the prepreg, that is, the total thickness of the core layer, the first and second resin layer be 5% or more and less than 40%, and more preferably 5% or more and less than 30%. When the thickness of the first resin layer is in the range, a fine circuit can be formed, and the obtained prepreg has excellent adhesion to the conductive material and flatness.

It is preferable that the thickness of the prepreg when the carrier film is excluded, that is, the total thickness of the core layer, and the first and second resin layer, be 120 μm or less, and more preferably in a range of 25 to 100 μm. When the thickness of the prepreg is in the range, embeddability of the conductive layer in the inner circuit board is excellent, and the multilayered substrate can be thinner.

Below, the wiring board according to the present invention will be explained.

The wiring board according to the present invention is produced by laminating the prepreg on the conductive circuit such that the conductive circuit is in contact with the second resin layer.

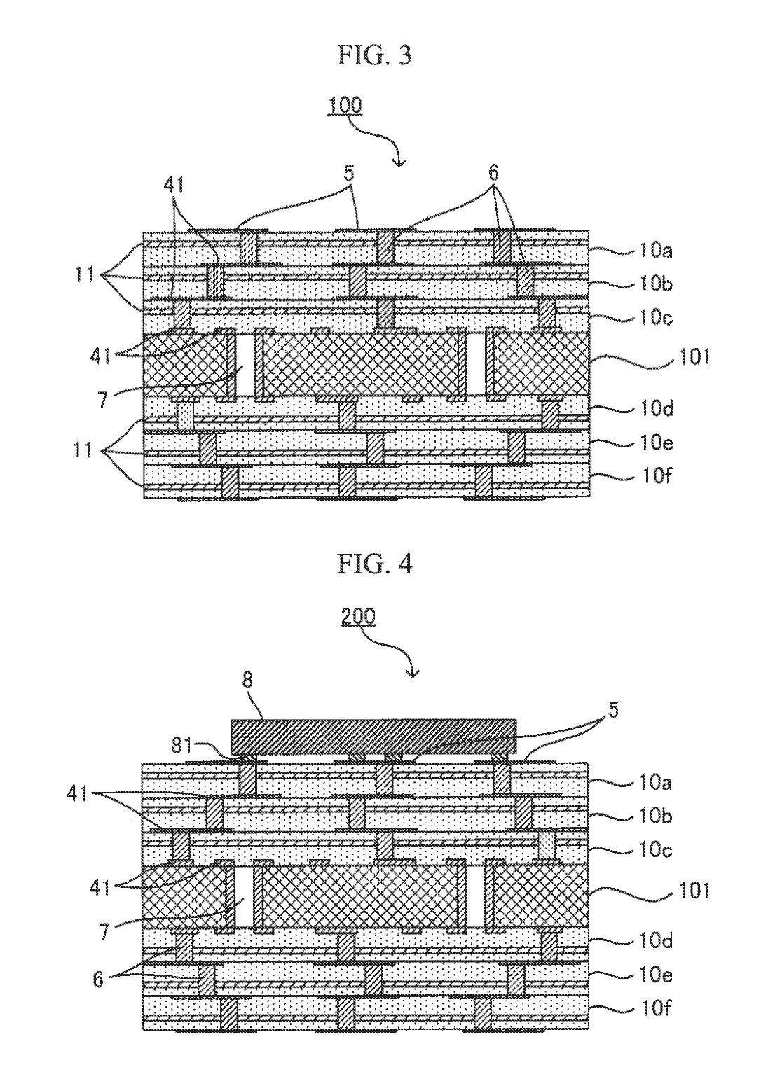

The wiring board according to the present invention will be explained in detail referring to the wiring board 100 having six layers in which the prepreg including three layers is laminated on both lower and upper surfaces of a core substrate, as shown in FIG. 3.

The wiring board 100 includes a core substrate 101 having a through-hole 7, the prepregs 10a, 10b, and 10c having three layers on the upper (upper side in FIG. 3) surface of the core substrate 101, and the prepregs 10d, 10e, and 10f having three layers on the lower (lower side in FIG. 3) surface of the core substrate 101.

A circuit layer 41 is formed between the core substrate 101 and the prepreg 10c, the core substrate 101 and the prepreg 10d, and between the prepregs 10a and 10b; 10b and 10c; 10d and 10e; and 10e and 10f. In addition, a pad 5 is formed on at least the surface of the prepreg 10a and 10f. It is preferable that the prepreg 10 having a thickness of 120 μm or less explained above be used as at least one, and preferably all of the prepregs 10a to 10f. When the prepreg 10 having a thickness of 120 μm or less explained above is used, the thickness of the wiring board 100 can be reduced.

Moreover, the circuit layers 41 are electrically connected to each other via a filled via 6 which is formed through the prepregs 10a to 10f.

In the prepregs 10a to 10f in the wiring board 100, the first epoxy resin composition constituting the first resin layer 2 on which the circuit layer 41 is formed, and the second epoxy resin composition constituting the second resin layer 3 which is formed on the opposite side relative to the core layer 11 have different compositions to each other. In other words, the first epoxy resin composition constituting the first resin layer 2 which is formed on the upper side of the prepregs 10a to 10c and the lower side of the prepregs 10d to 10f has a different composition from the second resin composition constituting the second resin layer 3 which is formed on the lower side of the prepregs 10a to 10c and the upper side of the prepregs 10d to 10f. The first epoxy resin composition constituting the first resin layer 2 has a composition which is excellent in adhesion to the conductive layer. The second epoxy resin composition constituting the second resin layer 3 has a composition which improves the embeddability of the circuit layer 41, and absorbs the stress from the conductive circuit which is embedded. In addition, the second resin layer 3 has a composition which can improve the low thermal expansibility. Due to this, the difference of the linear coefficient of thermal expansion between the circuit layer 41 and the second resin layer 3 is small, and the obtained wiring board 100 has excellent connection reliability to the insulating resin layer, and has small warpage.

In addition, the thickness of the wiring board 100 can be reduced by adjusting the thickness of the first resin layer 2 to a requisite minimum needed to obtain adhesion to the conductive layer, and the thickness of the second resin 3 to a requisite minimum needed to embed the circuit layer.

Moreover, the wiring board having six layers shown in FIG. 3 is explained above. However, the wiring board according to the present invention is not limited to this embodiment. The wiring board according to the present invention may be a multilayered substrate, for example, including three, four, five, seven, eight layers, or the like.

In addition, in the wiring board according to the present invention, the prepreg 10 in which the first epoxy resin composition constituting the first resin layer 2 and the second epoxy resin composition constituting the second resin layer 3 are different to each other and a conventional prepreg in which the first resin layer and the second resin layer have the same composition can be used at the same time.

Below, the semiconductor device according to the present invention will be explained.

The semiconductor device according to the present invention is produced by mounting a semiconductor element on the wiring board explained above.

For example, the semiconductor device 200 as shown in FIG. 4 can be produced by connecting a bump 81 of a semiconductor element 8 and the pad 5 of the wiring board 100 as shown in FIG. 3 to mount the semiconductor device 8 on the wiring board 100. Since the thickness of the first resin layer 2 and the second resin layer 3 of the prepreg 10a to 10f constituting the wiring board 100 can be adjusted to an optimal thickness, the thickness of the produced semiconductor device 200 can also be adjusted to an optimal thickness. Due to this, it is possible to produce a semiconductor device 200 having a requisite minimum thickness needed to satisfy required properties. Furthermore, the semiconductor device 200 produced by using the wiring board 100 has small warpage, and excellent mounting reliability.

### EXAMPLES

Below, the present invention will be further explained in detail referring to examples and comparative examples. However, the present invention is not limited to the examples.

First of all, an example of the prepreg will be explained. The composition and content (parts by weight) of the prepreg in Examples 1 to 21 are shown in Tables 1 to 3.

### Example 1

1. Preparation of First Epoxy Resin Composition

30 parts by weight of naphthalene-modified cresol novolac type epoxy resin (DIC Corporation Ltd., HP-500) as the epoxy resin, 20 parts by weight of bisphenyl aralkyl type phenol resin (Meiwa Plastic Industries, Ltd., MEH7851-5H) as the phenol curing agent, 30 parts by weight in terms of the solid contents of phenoxy resin (JER Co. Ltd., YX-8100BH30, solid content: 30% by weight) as the thermoplastic resin, 20 parts by weight of spherical silica having an average particle diameter of 75 nm (Tokuyama Corporation, NSS-5N) as the silica nanoparticles having an average particle diameter of 1 to 100 nm, and 0.5 parts by weight of imidazole (Shikoku Chemical Corporation, CUREZOL® 2E4MZ) as the curing agent were dissolved in methylethylketone so as to contain nonvolatile components of 45% by weight, and thereby the first epoxy resin composition was prepared.

2. Preparation of Second Epoxy Resin Composition

10 parts by weight of naphthalene-modified cresol novolac type epoxy resin (DIC Corporation Ltd., HP-500) as the epoxy resin, 10 parts by weight of bisphenyl aralkyl type phenol resin (Meiwa Plastic Industries, Ltd., MEH7851-4L) as the phenol curing agent, 20 parts by weight of phenol novolac type cyanate resin (LONZA Japan, Primaset PT-30), 60 parts by weight of spherical melt silica (Admatechs, SO-25R, average particle diameter: 0.5 μm) were dissolved in methylethylketone so as to contain nonvolatile components of 70% by weight, and thereby the second epoxy resin composition was prepared.

3. Preparation of Carrier Material

The prepared first epoxy resin composition was coated on an extremely thin copper foil with carrier (Mitsui Mining & Smelting Co., Ltd., Micro Thin® MTI8Ex-2 μm) using a comma coater such that the thickness of the resin layer after drying was 5.0 μm, and then dried at 160° C. for 5 minutes in a dryer, and thereby a resin sheet with a copper foil for the first resin layer was prepared.

In addition, similar to the resin sheet with a copper foil, the second epoxy resin composition was coated on a PET film (polyethylene terephthalate, Teijin DuPont Films, PUREX® film, thickness: 36 μm) and dried at 160° C. for 5 minutes in the dryer such that the thickness of the resin layer after drying was 27.5 μm, and thereby a resin sheet with a PET film for the second resin layer was prepared.

4. Preparation of Prepreg

The resin sheet with a copper foil for the first resin layer, and the resin sheet with a PET film for the second resin layer were arranged at both surfaces of a glass woven fabric (weight: 20 g; thickness: 20 μm; Nitto Boseki Co., Ltd., WTX-1027) such that the resin layer was in contact with the glass woven fabric, heated and pressurized at 0.5 MPa and 140° C. for 1 minute under vacuum to make the epoxy resin compositions infiltrate into the glass woven fabric, and thereby a prepreg including the carrier films was produced. In the obtained prepreg, the thickness of the first resin layer, the core layer, and the second resin layer was 5 μm, 20 μm, and 15 μm, respectively, that is, the total thickness of the prepreg was 40 μm. The thickness of the first resin layer relative to the thickness of the prepreg, that is, the total thickness of the core layer, the first and second resin layers, was 12.5%.

5. Preparation of Wiring Board and Semiconductor Device

An inner circuit substrate was prepared by forming a circuit pattern (remaining copper rate: 70%, L/S=50/50 μm) on a core substrate (Sumitomo Bakelight Co., Ltd., ELC-4785GS-B, thickness: 0.4 mm; 12 μm-copper foil). After that, the PET film of the prepreg obtained was peeled, and the prepreg was superimposed on both surfaces of the inner circuit substrate with the circuit pattern such that the second resin layer was in contact with the inner circuit substrate. Then, the laminate was heated and pressurized to mold in a vacuum pressurization type laminator device at 150° C. and 1 MPa for 120 seconds. After that, the obtained laminate was put in a hot wind-dryer at 220° C. for 60 minutes to be cured. Thereby, a multilayered wiring board was produced.

The carrier copper foil was peeled from the multilayered wiring board obtained, and the extremely-thin copper foil was removed by etching. Then, a blind via hole (which is not a through-hole) was formed using a carbonate laser. The inside of the via hole and the surface of the first resin layer was immersed in a swelling conditioner (Atotech Japan Co., Ltd.; Swelling Dip Securinganth P) at 60° C. for 5 minutes, and then further immersed in an aqueous solution of potassium permagnate (Atotech Japan Co., Ltd.; Concentrate Compact CP) at 80° C. for 10 minutes. Thereby it was neutralized to be roughed.

Then, the product was subjected to degreasing, application of catalyst, and activating. After that, a fine circuit having L/S of 12/12 μm was processed by forming a copper film having a thickness of 1 μm by an electroless plating, forming a plating resist, then forming a patterned electroplated copper film having a thickness of 12 μm using the electroless plated copper film as a power supply layer. After annealing in a hot wind-dryer at 200° C. for 60 minutes, the power supply layer was removed by flash etching.

Then, a solder resist (Taiyo Ink MFG. Co., Ltd.; PSR-4000 AUS703) was printed, a mask was formed so as to expose the desired semiconductor element mounting pad, developed and cured, and thereby a solder resist layer having a thickness of 12 μm was formed on the circuit.

Finally, a plating layer including an electroless plated nickel layer having a thickness of 3 μm, and an electroless plated gold layer having a thickness of 0.1 μm which was formed on the electroless plated nickel layer was formed on the circuit exposed from the solder resist layer. Then, the produced substrate was cut into 50 mm×50 mm size, and thereby a multilayered wiring board for a semiconductor device was produced.

The semiconductor device was produced by mounting with heat and pressure a semiconductor device having solder bumps (TEG chip; size: 15 mm×15 mm; thickness: 0.6 mm) on the multilayered wiring board for a semiconductor device produced using a flip-chip bonder device; then the solder bumps were melted and adhered to the multilayered wiring board by an IR reflow oven; and a liquid sealing resin (Sumitomo Bakelite Co, Ltd., CRP-4152S) was filled and hardened. Moreover, the liquid sealing resin used was hardened at 150° C. for 120 minutes. In addition, the solder bumps used were made of an eutectic Sn/Pb alloy.

### Example 2

The semiconductor device was produced in a manner identical to that of Example 1, except that when preparing the first epoxy resin composition, 20 parts by weight of phenol novolac type cyanate (LONZA Japan, Primaset PT-30) and 0.3 parts by weight of CUREZOL® 1B2PZ (Shikoku Chemical Corporation) were used instead of biphenyl aralkyl type phenol resin and CUREZOL® 2E4MZ.

### Example 3

The semiconductor device was produced in a manner identical to that of Example 2, except that when preparing the first epoxy resin composition, 30 parts by weight of anthracene type epoxy resin (JER Co. Ltd., YX-8800) was used instead of naphthalene-modified cresol novolac epoxy resin.

### Example 4

The semiconductor device was produced in a manner identical to that of Example 2, except that when preparing the first epoxy resin composition, 30 parts by weight of naphthalene dimethylene type epoxy resin (TOHOTO Chemical Industries Co. Ltd., ESN-175) was used instead of naphthalene-modified cresol novolac epoxy resin.

### Example 5

The semiconductor device was produced in a manner identical to that of Example 2, except that when preparing the first epoxy resin composition, 30 parts by weight of biphenyl dimethylene type epoxy resin (Nippon Kayaku Co. Ltd., NC-3000) was used instead of naphthalene-modified cresol novolac epoxy resin.

### Example 6

The semiconductor device was produced in a manner identical to that of Example 2, except that when preparing the first epoxy resin composition, 30 parts by weight of cresol novolac type epoxy resin (DIC Co. Ltd., N-690) was used instead of naphthalene-modified cresol novolac epoxy resin.

### Example 7

The semiconductor device was produced in a manner identical to that of Example 2, except that when preparing the first epoxy resin composition, 30 parts by weight of silicone-modified polyimide resin was used instead of bis S/biphenyl type phenoxy resin.

Below, the synthetic method for the silicone-modified polyimide resin (Synthesis Example 1) will be explained in detail.

### Synthesis Example 1

220.24 g of anisole and 55.06 g of toluene were put into a four-neck separable flask having a thermometer, stirrer, and inlet for raw materials. Then, 43.38 g (0.0833 mol) of 4,4′-bisphenol A acid dianydride was added, and suspended in the anisole and toluene. After that, 23.39 g (0.05 mol) of 2,2-bis(4-(4-aminophenoxy)phenyl)propane and 27.87 g (0.0333 mol) of α, ω-bis(3-aminopropyl)polydimethyl siloxane (average molecular weight: 836) were put into the flask as diamine components, and amic acid was produced.

Then, a Dean-Stark reflux condenser was installed. When the amic acid was heated using an oil-bath, the suspension was dissolved, and the solution was clear. At this time, water generated by the imidization was removed by azeotropy with toluene. After heating and refluxing for 2 hours, the reaction was finished. After cooling, the reaction product was put into a large amount of methanol to precipitate polyimide. After filtrating the solid contents, the obtained solid contents were dried under reduced pressure at 70 to 80° C. for 12 hours to remove the solvent. Thereby the solid polyimide resin 1 was produced. The weight average molecular weight (Mw) of the polyimide resin 1 was 46,000.

### Example 8

The semiconductor device was produced in a manner identical to that of Example 2, except that when preparing the first epoxy resin composition, 30 parts by weight of rubber-modified phenolic hydroxyl group-containing polyamide was used instead of bis S/biphenyl type phenoxy resin.

Below, the synthetic method for the rubber-modified hydroxyl group-containing polyamide (Synthesis Example 2) will be explained in detail.

### Synthesis Example 2

A 500 ml-flask equipped with a thermometer, cooling pipe, and stirrer was purged with nitrogen gas. Then, 14.6 g (0.080 mol) of 5-hydroxyisophthalic acid, 50.5 g (0.304 mol) of isophthalic acid, 121.6 g (0.416 mol) of 1,3-bis(3-aminophenoxy)benzene, 9.0 g of lithium chloride, 860 g of N-methylpyrrolidone, and 170 g of pyridine were put into the flask, and stirred to dissolve. After that, 200 g of triphenyl phosphite was added, and reacted at 95° C. for 8 hours, and the phenolic hydroxyl group-containing polyamide resin was produced. Then, a solution, in which 100 g of terminal carboxyl group-modified polybutadiene-acrylonitrile rubber (Ube Industries Ltd., HycarCTBN2000X162; weight average molecular weight: 3,600) was dissolved in 165 g of pyridine and 180 g of N-methylpyrrolidone, was added to the obtained phenolic hydroxyl group-containing polyamide resin, and they were further reacted for 4 hours. The produced polymer solution was deposited in a poor solvent, methanol, and filtrated. Then, the filtrated product was washed with methanol repeatedly. After that, the washed product was dried in an oven at 80° C., and thereby a solid rubber-modified phenolic hydroxyl group-containing polyamide was produced.

### Example 9

The semiconductor device was produced in a manner identical to that of Example 2, except that when preparing the first epoxy resin composition, 30 parts by weight of rubber-modified phenolic hydroxyl group-containing polyamide (Nippon Kayaku Co. Ltd.; KAYAFLEX BPAM-155) was used instead of bis S/biphenyl type phenoxy resin.

### Example 10

The semiconductor device was produced in a manner identical to that of Example 2, except that when preparing the first epoxy resin composition, 30 parts by weight of rubber-modified phenolic hydroxyl group-containing polyamide (Nippon Kayaku Co. Ltd.; KAYAFLEX BPAM-01) was used instead of bis S/biphenyl type phenoxy resin.

### Example 11

The semiconductor device was produced in a manner identical to that of Example 9, except that when preparing the first epoxy resin composition, the content of the naphthalene-modified cresol novolac type epoxy resin, the phenol novolac type cyanate resin, the rubber-modified phenolic hydroxyl group-containing polyamide (Nippon Kayaku Co. Ltd.; KAYAFLEX BPAM-155), and the silica nanoparticles (NSS-5N) was changed to 36 parts by weight, 18 parts by weight, 36 parts by weight, and 10 parts by weight, respectively.

### Example 12

The semiconductor device was produced in a manner identical to that of Example 9, except that when preparing the first epoxy resin composition, the content of the naphthalene-modified cresol novolac type epoxy resin, the phenol novolac type cyanate resin, the rubber-modified phenolic hydroxyl group-containing polyamide (Nippon Kayaku Co. Ltd.; KAYAFLEX BPAM-155), and the silica nanoparticles (NSS-5N) was changed to 38 parts by weight, 19 parts by weight, 38 parts by weight, and 5 parts by weight, respectively.

### Example 13

The semiconductor device was produced in a manner identical to that of Example 2, except that when preparing the first epoxy resin composition, 30 parts by weight of polyether sulfone resin (Sumitomo Chemical Co., Ltd.; PES5003P) was used instead of bis S/biphenyl type phenoxy resin.

### Example 14

The semiconductor device was produced in a manner identical to that of Example 2, except that when preparing the first epoxy resin composition, 30 parts by weight of polyphenyleneoxide resin (Mitsubishi Gas Chemical Company; OPE-2st) was used instead of bis S/biphenyl type phenoxy resin.

### Example 15

The semiconductor device was produced in a manner identical to that of Example 2, except that when preparing the first epoxy resin composition, silica nanoparticles (Admatechs, Admanano; average particle diameter: 56 nm, treated with vinylsilane) was used instead of silica nanoparticles (NSS-5N).

### Example 16

The semiconductor device was produced in a manner identical to that of Example 15, except that when preparing the first epoxy resin composition, the content of the naphthalene-modified cresol novolac type epoxy resin, the phenol novolac type cyanate resin, the bis S/biphenyl type phenoxy resin, silica nanoparticles (Admatechs, Admanano; average particle diameter: 56 nm, treated with vinylsilane) was changed to 24 parts by weight, 24 parts by weight, 12 parts by weight, and 2 parts by weight respectively, and 38 parts by weight of the spherical silica (Tokuyama Corporation; NSS-3N, average particle diameter: 0.125 μm) was further added.

### Example 17

The semiconductor device was produced in a manner identical to that of Example 9, except that when preparing the first epoxy resin composition, 10 parts by weight of silica nanoparticles (Admatechs, Admanano; average particle diameter: 56 nm, treated with vinylsilane) and 5 parts by weight of the spherical silica (Tokuyama Corporation; NSS-3N, average particle diameter: 0.125 μm) were used instead of the silica nanoparticles (NSS-5N).

### Example 18

The semiconductor device was produced in a manner identical to that of Example 9, except that when preparing the first epoxy resin composition, 2 parts by weight of silica nanoparticles (Admatechs, Admanano; average particle diameter: 56 nm, treated with vinylsilane) and 18 parts by weight of boehmite (Kawai Lime Industry Co., Ltd; BMB; average particle diameter: 0.5 μm) were used instead of the silica nanoparticles (NSS-5N).

### Example 19

The semiconductor device was produced in a manner identical to that of Example 17, except that when preparing the second epoxy resin composition, the content of the naphthalene-modified cresol novolac epoxy resin, biphenyl aralkyl type phenol resin, phenol novolac type cyanate resin, and the spherical silica (Admatechs, SO-25R; 0.5 μm) was changed to 7.5 parts by weight, 7.5 parts by weight, 15 parts by weight, and 70 parts by weight, respectively.

### Example 20

The semiconductor device was produced in a manner identical to that of Example 19, except that when preparing the second epoxy resin composition, 7.5 parts by weight of biphenyl dimethylene type epoxy resin (Nippon Kayaku Co. Ltd.; NC-3000) was used instead of naphthalene-modified cresol novolac epoxy resin.

### Example 21

The semiconductor device was produced in a manner identical to that of Example 19, except that when preparing the second epoxy resin composition, 7.5 parts by weight of dicyclopentadiene type epoxy resin (DIC Co. Ltd.; HP-7200L) was used instead of naphthalene-modified cresol novolac epoxy resin.

### Example 22

The semiconductor device was produced in a manner identical to that of Example 21, except that when preparing the first carrier material, a PET film including a sputter-deposited copper thin film having a thickness of 1 μm was used, and a resin layer was formed on the deposited copper thin film.

### Example 23

The semiconductor device was produced in a manner identical to that of Example 21, except that when preparing the first carrier material, a first epoxy composition as varnish was coated on a PET film.

### Example 24

The semiconductor device was produced in a manner identical to that of Example 16, except that when preparing the carrier material, the first epoxy resin composition was coated such that the thickness of the first resin layer after drying was 2.0 μm, and the second epoxy resin composition was coated such that the thickness of the second resin layer after drying was 30.5 μM. Moreover, the thickness of the first resin layer, the core layer, and the second resin layer was 2 μm, 20 μm, and 18 μm, respectively, and the total thickness of the prepreg was 40 μm. The percentage of the thickness of the first resin layer relative to the thickness of the prepreg, that is, the total thickness of the first and second resin layers and the core layer, was 5%.

### Example 25

The semiconductor device was produced in a manner identical to that of Example 16, except that when preparing the carrier material, the first epoxy resin was coated such that the thickness of the first resin layer after drying was 8.0 μm, and the second epoxy resin was coated such that the thickness of the second resin layer after drying was 24.5 μm. Moreover, the thickness of the first resin layer, the core layer, and the second resin layer was 8 μm, 20 μm, and 12 μm, respectively, and the total thickness of the prepreg was 40 μm. The percentage of the thickness of the first resin layer relative to the thickness of the prepreg, that is, the total thickness of the first and second resin layers and the core layer, was 20%.

### Comparative Example 1

The prepreg containing 67% by weight of epoxy resin composition in terms of solid contents was produced in a manner identical to that of Example 1, except that a glass woven fabric (weight: 20 g; thickness: 20 μm; Nitto Boseki Co., Ltd., T glass woven fabric; WTX-1027) was immersed into the second epoxy resin composition as varnish, and dried in a heating oven at 180° C. for 2 minutes. In addition, the wiring board and the semiconductor device were also produced similar to Example 1.

### Comparative Example 2

The semiconductor device was produced in a manner identical to that of Example 1, except that when preparing the first epoxy resin composition, spherical silica having an average particle diameter of 1.0 μm (Admatechs, SO-32R) was used instead of the silica nanoparticles having an average particle diameter in a range of 1 to 100 nm.

### Comparative Example 3

The semiconductor device was produced in a manner identical to that of Example 1, except that when preparing the first epoxy resin composition, the silica nanoparticles having an average particle diameter in a range of 1 to 100 nm were not used.

(Evaluation)

The following evaluations of the prepreg, wiring board, and semiconductor device prepared in Examples and Comparative Examples were carried out. The evaluations are explained below. In addition, the results of evaluation are shown in Tables 4 and 5.

(1) Melt Viscosity

The lowest melt viscosity was measured using a viscoelasticity measurement device (Anton Paar, Physica MCR Series) under conditions in which the rate of temperature increase was 5° C./min. frequency was 1 Hz, amplitude was 0.3%, and load was 0.1 N.

The sample having a thickness of 80 μm for evaluation was produced by coating the second epoxy resin composition as varnish on a PET film such that the thickness of the resin layer after drying was 40 μM, drying in a dryer at 160° C. for 5 minutes to produce a resin sheet, and superimposing the two resin sheets produced on each other.

(2) Embeddability

The outer copper foil of the multilayered wiring board after curing with heat, as already produced in “5. Preparation of Wiring Board and Semiconductor Device”, was entirely etched, then the inner pattern and cross-section were observed.

The results were evaluated as shown below.

Excellent: No problems in embeddability in the entirety of the wiring board

Good: Substantially no problem (defect was observed at the edge of the substrate of the individual piece, which is non-product)

Inferior: Defect was observed in pattern embedding

(3) Coefficient of Thermal Expansion (50 to 100° C.)

A test piece having a size of 4 mm×20 mm was heated using TMA device (Thermal Mechanical Analyzer) (TA Instrument; Q4000) by raising the temperature from 30 to 300° C. at a rate of temperature increase of 10° C./min and load of 5 g as one cycle. Then, the coefficient of thermal expansion (CTE) of the test piece was measured at 50 to 100° C. in the second cycle.

Moreover, the sample for evaluation was produced by superimposing two prepregs obtained such that the second resin layers were in contact with each other, and laminated with pressure at 220° C., and pressure of 1 PMa for 120 minutes, and then removing the copper foils.

(4) Arithmetic Mean Roughness (Ra)

As the arithmetic mean roughness (Ra) at the surface of insulating layer, the arithmetic mean roughness at the surface of the first resin layer was measured using Veeco Instrument Inc., WYKO NT1100 in accordance with JIS B0601. Moreover, as a test piece for evaluation, the multilayered wiring board produced in “5. Preparation of Wiring Board and Semiconductor Device” after roughening treatment was used.

(5) Peel Strength (kN/m)

Peel strength was measured in accordance with JIS C6481. Moreover, a test piece for evaluation having a thickness of 30 μm was produced by making a copper film having a thickness of 1 μm by electroless plating as disclosed in “5. Preparation of Wiring Board and Semiconductor Device”, and a copper film having a thickness of 29 μm by electroplating on the produced multilayered wiring board.

(6) Appearance after PCT (Pressure Cooker Test)

Appearance, such as presence of blister, or the like of a test piece was observed after treatment using a saturate pressure cooker device under conditions that the temperature was 121° C. and humidity was 100% for 196 hours. Moreover, the test piece was a substrate of the multilayered wiring board before forming the solder resist in “5 Preparing of Wiring Board and Semiconductor Device”.

The results were evaluated as shown below.

Excellent: No problem

Good: Substantially no problem (defect was observed at the edge of the substrate of the individual piece, which is non-product)

Inferior: Blister was observed in the circuit pattern

(7) Fine Wiring Workability

The appearance of the pattern having 12/12 μm of L/S of the multilayered wiring board before formation of the solder resist in “5. Preparation of Wiring Board and Semiconductor Device” was observed using a laser microscope. In addition, continuity of the pattern was also evaluated.

The results were evaluated as shown below.

Excellent: Both appearance and continuity had no problem

Good: Substantially no problem, no short and wiring defect

Inferior: Short and wiring defect were confirmed

(8) Warp of Multilayered Wiring Board

The multilayered wiring board produced in “5. Preparation of Wiring Board and Semiconductor Device” was cut into a test piece having a size of 50 mm×50 mm, and the displacement of the test piece in the height direction was measured using a temperature-variable laser three-dimensional measurement device (Hitachi Technologies and Services, Ltd; Model LS220-MT100MT50), and the largest displacement was used as wrap amount.

The results were evaluated as shown below.

Excellent: Wrap amount of 100 μm or less

Good: Wrap amount of more than 100 μm and less than 150 μm

Inferior: Wrap amount of 150 μm or more

(9) Reliability in Insulation Properties (HAST: High Accelerated Stress Test)

On the pattern (L/S=12/12 μm) of the multilayered wiring board before formation of the solder resist in “5. Preparation of Wiring Board and Semiconductor Device”, an insulating resin sheet (Sumitomo Bakelite Co., Ltd.; BLA-3700GS) was laminated instead of printing the solder resist, and hardened at 220° C. Then the insulation resistance was measured continuously under conditions in which the temperature was 130° C., the humidity was 85%, and applied voltage: 3.3 V. Moreover, when the resistance was 10⁶Ω or less, the test piece was regarded as faulty.

The results were evaluated as shown below.

Excellent: No fault over 300 hours

Good: Faulty at 150 hours or longer and less than 300 hours

Inferior: Faulty at less than 150 hours

(10) Warp of Semiconductor

As the warp amount of the semiconductor device, the semiconductor device was set in the sample chamber of the temperature-variable laser three-dimensional measurement device (Hitachi Technologies and Services, Ltd; Model LS220-MT100MT50) such that the surface of the element faced downward, the displacement amount in the height direction of the semiconductor device was measured, and the largest displacement was used as a wrap amount.

The results were evaluated as shown below.

Excellent: Wrap amount of 100 μm or less

Good: Wrap amount of more than 100 μm and less than 150 μm

Inferior: Wrap amount of 150 μm or more

TABLE 1

| | | | Example | | | | | | |
|---|---|---|---|---|---|---|---|---|---|
| | | | 1 | 2 | 3 | 4 | 5 | 6 | 7 |
| First | Epoxy resin | Naphthalene-modified cresol novolac epoxy resin | 30 | 30 | | | | | 30 |
| epoxy | | Anthracene type epoxy resin | | | 30 | | | | |
| resin | | Naphthalene dimethylene type epoxy resin | | | | 30 | | | |
| composition | | Biphenyl dimethylene type epoxy resin | | | | | 30 | | |
| | | Cresol novolac type epoxy resin | | | | | | 30 | |
| | Other thermosetting | Biphenyl aralkyl type phenol resin | 20 | | | | | | |
| | resin | Phenol novlac type cyanate resin | | 20 | 20 | 20 | 20 | 20 | 20 |
| | Thermoplastic resin | Bis S/biphenyl type phenoxy resin | 30 | 30 | 30 | 30 | 30 | 30 | |
| | | Silicone-modified Polyimide resin | | | | | | | 30 |
| | | (synthetic example 1) | | | | | | | |
| | | Rubber-modified phenolic OH-containing polyamide | | | | | | | |
| | | (synthetic example 2) | | | | | | | |
| | | Rubber-modified phenolic OH-containing polyamide | | | | | | | |
| | | (BPHAM-155) | | | | | | | |
| | | Rubber-modified phenolic OH-containing polyamide | | | | | | | |
| | | (BPHAM-01) | | | | | | | |
| | | Polyethersulfone resin | | | | | | | |
| | | Polyphenylene oxide resin | | | | | | | |
| | Silica nanoparticles | NSS-5N (average particle size: 75 nm) | 20 | 20 | 20 | 20 | 20 | 20 | 20 |
| | having an average | Admanano (average particle size: 56 nm) | | | | | | | |
| | particles size of | | | | | | | | |
| | 1-100 um | | | | | | | | |
| | Spherical silica | NSS-3N (average particle size: 0.125 μm) | | | | | | | |
| | Other filler | Boehmite (BMB; average particle size: 0.5 μm) | | | | | | | |
| | Curing catalyst | CUREZOL ® 2E4MZ | 0.5 | | | | | | |
| | | CUREZOL ® 1B2PZ | | 0.3 | 0.3 | 0.3 | 0.3 | 0.3 | 0.3 |
| Second | Epoxy resin | Naphthalene-modified cresol novolac epoxy resin | 10 | 10 | 10 | 10 | 10 | 10 | 10 |
| epoxy | | Biphenyl dimethylene type epoxy resin | | | | | | | |
| resin | | Dicyclopentadiene type epoxy resin | | | | | | | |
| composition | Curing resin | Biphenylaralkyl type phenol resin | 10 | 10 | 10 | 10 | 10 | 10 | 10 |
| | Cyanate resin | Phenol novolac type cyanate resin | 20 | 20 | 20 | 20 | 20 | 20 | 20 |
| | Inorganic filler | Spherical silica SO-25R (average particle | 60 | 60 | 60 | 60 | 60 | 60 | 60 |
| | | diameter: 0.5 μm) | | | | | | | |

TABLE 2

| | | | Example | | | | | | |
|---|---|---|---|---|---|---|---|---|---|
| | | | 8 | 9 | 10 | 11 | 12 | 13 | 14 |
| First | Epoxy resin | Naphthalene-modified cresol novolac epoxy resin | 30 | 30 | 30 | 36 | 38 | 30 | 30 |
| epoxy | | Anthracene type epoxy resin | | | | | | | |
| resin | | Naphthalene dimethylene type epoxy resin | | | | | | | |
| composition | | Biphenyl dimethylene type epoxy resin | | | | | | | |
| | | Cresol novolac type epoxy resin | | | | | | | |
| | Other thermosetting | Biphenyl aralkyl type phenol resin | | | | | | | |
| | resin | Phenol novolac type cyanate resin | 20 | 20 | 20 | 18 | 19 | 20 | 20 |
| | Thermoplastic resin | Bis S/biphenyl type phenoxy resin | | | | | | | |
| | | Silicone-modified polyimide resin | | | | | | | |
| | | (synthetic example 1) | | | | | | | |
| | | Rubber-modified phenolic OH-containing polyamide | 30 | | | | | | |
| | | (synthetic example 2) | | | | | | | |
| | | Rubber-modified phenolic OH-containing polyamide | | 30 | | 36 | 38 | | |
| | | (BPHAM-155) | | | | | | | |
| | | Rubber-modified phenolic OH-containing polyamide | | | 30 | | | | |
| | | (BPHAM-01) | | | | | | | |
| | | Polyethersulfone resin | | | | | | 30 | |
| | | Polyphenylene oxide resin | | | | | | | 30 |
| | Silica nanoparticles | NSS-5N (average particle size: 75 nm) | 20 | 20 | 20 | 10 | 5 | 20 | 20 |
| | having an average | Admanano (average particle size: 56 nm) | | | | | | | |
| | particles size of | | | | | | | | |
| | 1-100 um | | | | | | | | |
| | Spherical silica | NSS-3N (average particle size: 0.125 μm) | | | | | | | |
| | Other filler | Boehmite (BMB; average particle size: 0.5 μm) | | | | | | | |
| | Curing catalyst | CUREZOL ® 2E4MZ | | | | | | | |
| | | CUREZOL ® 1B2PZ | 0.3 | 0.3 | 0.3 | 0.3 | 0.3 | 0.3 | 0.3 |
| Second | Epoxy resin | Naphthalene-modified cresol novolac epoxy resin | 10 | 10 | 10 | 10 | 10 | 10 | 10 |
| epoxy | | Biphenyl dimethylene type epoxy resin | | | | | | | |
| resin | | Dicyclopentadiene type epoxy resin | | | | | | | |
| composition | Curing resin | Biphenyl aralkyl type phenol resin | 10 | 10 | 10 | 10 | 10 | 10 | 10 |
| | Cyanate resin | Phenol novolac type cyanate resin | 20 | 20 | 20 | 20 | 20 | 20 | 20 |
| | Inorganic filler | Spherical silica SO-25R (average particle | 60 | 60 | 60 | 60 | 60 | 60 | 60 |
| | | diameter: 0.5 μm) | | | | | | | |

TABLE 3

| | | | Example | | | | | | |
|---|---|---|---|---|---|---|---|---|---|
| | | | 15 | 16 | 17 | 18 | 19 | 20 | 21 |
| First | Epoxy resin | Naphthalene-modified cresol novolac epoxy resin | 30 | 24 | 30 | 30 | 30 | 30 | 30 |
| epoxy | | Anthracene type epoxy resin | | | | | | | |
| resin | | Naphthalene dimethylene type epoxy resin | | | | | | | |
| composition | | Biphenyl dimethylene type epoxy resin | | | | | | | |
| | | Cresol novolac type epoxy resin | | | | | | | |
| | Other thermosetting | Biphenyl aralkyl type phenol resin | | | | | | | |
| | resin | Phenol novlac type cyanate resin | 20 | 24 | 20 | 20 | 20 | 20 | 20 |
| | Thermoplastic resin | Bis S/biphenyl type phenoxy resin | 30 | 12 | | | | | |
| | | Silicone-modified polyimide resin | | | | | | | |
| | | (synthetic example 1) | | | | | | | |
| | | Rubber-modified phenolic OH-containing polyamide | | | | | | | |
| | | (synthetic example 2) | | | | | | | |
| | | Rubber-modified phenolic OH-containing polyamide | | | 30 | 30 | 30 | 30 | 30 |
| | | (BPHAM-155) | | | | | | | |
| | | Rubber-modified phenolic OH-containing polyamide | | | | | | | |
| | | (BPHAM-01) | | | | | | | |
| | | Polyethersulfone resin | | | | | | | |
| | | Polyphenylene oxide resin | | | | | | | |
| | Silica nanoparticles | NSS-5N (average particle size: 75 nm) | | | | | | | |
| | having an average | Admanano (average particle size: 56 nm) | 20 | 2 | 10 | 2 | 10 | 10 | 10 |
| | particles size of | | | | | | | | |
| | 1-100 um | | | | | | | | |
| | Spherical silica | NSS-3N (average particle size: 0.125 μm) | | 38 | 5 | | 5 | 5 | 5 |
| | Other filler | Boehmite (BMB; average particle size: 0.5 μm) | | | | 18 | | | |
| | Curing catalyst | CUREZOL ® 2E4MZ | | | | | | | |
| | | CUREZOL ® 1B2PZ | 0.3 | 0.3 | 0.3 | 0.3 | 0.3 | 0.3 | 0.3 |
| Second | Epoxy resin | Naphthalene-modified cresol novolac epoxy resin | 10 | 10 | 10 | 10 | 7.5 | | |
| epoxy | | Biphenyl dimethylene type epoxy resin | | | | | | 7.5 | |
| resin | | Dicyclopentadiene type epoxy resin | | | | | | | 7.5 |
| composition | Curing resin | Biphenyl aralkyl type phenol resin | 10 | 10 | 10 | 10 | 7.5 | 7.5 | 7.5 |
| | Cyanate resin | Phenol novolac type cyanate resin | 20 | 20 | 20 | 20 | 15 | 15 | 15 |
| | Inorganic filler | Spherical silica SO-25R (average particle | 60 | 60 | 60 | 60 | 70 | 70 | 70 |
| | | diameter: 0.5 μm) | | | | | | | |

TABLE 4

| | | Example | | | | | | |
|---|---|---|---|---|---|---|---|---|
| | | 1 | 2 | 3 | 4 | 5 | 6 | 7 |
| (1) | Melt viscosity (Pa · s) | 200 | 200 | 200 | 200 | 200 | 200 | 200 |
| (2) | Embedability | Excellent | Excellent | Excellent | Excellent | Excellent | Excellent | Excellent |
| (3) | Coefficient of thermal expansion | 13 | 13 | 13 | 13 | 13 | 13 | 13 |
| | (50-100° C.) (ppm) | | | | | | | |
| (4) | Arithmetic mean roughness (Ra)(μm) | 0.45 | 0.45 | 0.45 | 0.45 | 0.45 | 0.45 | 0.50 |
| (5) | Peel strength (kN/m) | 0.75 | 0.85 | 0.80 | 0.80 | 0.80 | 0.75 | 0.80 |
| (6) | Appearance after PCT | Good | Excellent | Excellent | Excellent | Excellent | Good | Excellent |
| (7) | Fine wiring workability (L/S = 15/15) | Excellent | Excellent | Excellent | Excellent | Excellent | Excellent | Good |
| (8) | Wrap of multilayered wiring board | Good | Good | Good | Good | Good | Good | Good |
| (9) | Reliability in insulating properties | Good | Excellent | Excellent | Excellent | Excellent | Good | Excellent |
| | (LS10, HAST, 3.3 V) | | | | | | | |
| (10) | Wrap of semiconductor | Good | Excellent | Excellent | Excellent | Excellent | Excellent | Excellent |
| | | Example | | | | | | |
| | | 8 | 9 | 10 | 11 | 12 | 13 | 14 |
| (1) | Melt viscosity (Pa · s) | 200 | 200 | 200 | 200 | 200 | 200 | 200 |
| (2) | Embedability | Excellent | Excellent | Excellent | Excellent | Excellent | Excellent | Excellent |
| (3) | Coefficient of thermal expansion | 13 | 13 | 13 | 13 | 14 | 13 | 13 |
| | (50-100° C.) (ppm) | | | | | | | |
| (4) | Arithmetic mean roughness (Ra)(μm) | 0.45 | 0.45 | 0.45 | 0.40 | 0.40 | 0.45 | 0.45 |
| (5) | Peel strength (kN/m) | 0.90 | 0.95 | 0.90 | 0.95 | 0.95 | 0.80 | 0.80 |
| (6) | Appearance after PCT | Excellent | Excellent | Excellent | Excellent | Excellent | Good | Excellent |
| (7) | Fine wiring workability (L/S = 15/15) | Excellent | Excellent | Excellent | Excellent | Excellent | Excellent | Excellent |
| (8) | Wrap of multilayered wiring board | Good | Excellent | Good | Excellent | Excellent | Good | Good |
| (9) | Reliability in insulating properties | Excellent | Excellent | Excellent | Excellent | Excellent | Excellent | Excellent |
| | (LS10, HAST, 3.3 V) | | | | | | | |
| (10) | Wrap of semiconductor | Excellent | Excellent | Excellent | Excellent | Good | Excellent | Excellent |

TABLE 5

| | | Example | | | | | | |
|---|---|---|---|---|---|---|---|---|
| | | 15 | 16 | 17 | 18 | 19 | 20 | 21 |
| (1) | Melt viscosity (Pa · s) | 200 | 200 | 200 | 200 | 1,200 | 1,500 | 900 |
| (2) | Embedability | Excellent | Excellent | Excellent | Excellent | Good | Good | Excellent |
| (3) | Coefficient of thermal expansion | 13 | 12 | 13 | 14 | 12 | 11 | 13 |
| | (50-100° C.) (ppm) | | | | | | | |
| (4) | Arithmetic mean roughness (Ra)(μm) | 0.50 | 0.50 | 0.45 | 0.50 | 0.45 | 0.45 | 0.45 |
| (5) | Peel strength (kN/m) | 0.80 | 0.75 | 0.95 | 0.75 | 0.95 | 0.95 | 0.95 |
| (6) | Appearance after PCT | Excellent | Excellent | Excellent | Excellent | Excellent | Excellent | Excellent |
| (7) | Fine wiring workability (L/S = 15/15) | Good | Good | Excellent | Good | Excellent | Excellent | Excellent |
| (8) | Wrap of multilayered wiring board | Good | Excellent | Good | Good | Good | Good | Good |
| (9) | Reliability in insulating properties | Good | Excellent | Excellent | Excellent | Excellent | Excellent | Excellent |
| | (LS10, HAST, 3.3 V) | | | | | | | |
| (10) | Wrap of semiconductor | Excellent | Excellent | Excellent | Good | Excellent | Excellent | Excellent |

| | | Example | | | | | | |
|---|---|---|---|---|---|---|---|---|
| | | 22 | 23 | 24 | 25 | 1 | 2 | 3 |
| (1) | Melt viscosity (Pa · s) | 900 | 900 | 200 | 200 | 200 | 200 | 200 |
| (2) | Embedability | Excellent | Excellent | Excellent | Excellent | Inferior | Excellent | Excellent |
| (3) | Coefficient of thermal expansion | 13 | 13 | 12 | 12 | 15 | 13 | 15 |
| | (50-100° C.) (ppm) | | | | | | | |
| (4) | Arithmetic mean roughness (Ra)(μm) | 0.45 | 0.15 | 0.50 | 0.50 | 0.75 | 0.65 | 0.15 |
| (5) | Peel strength (kN/m) | 0.95 | 0.85 | 0.70 | 1.10 | 0.30 | 0.85 | 0.35 |
| (6) | Appearance after PCT | Excellent | Excellent | Excellent | Excellent | Inferior | Excellent | Inferior |
| (7) | Fine wiring workability (L/S = 15/15) | Excellent | Excellent | Good | Good | Inferior | Inferior | Inferior |
| (8) | Wrap of multilayered wiring board | Good | Good | Excellent | Good | Inferior | Good | Inferior |
| (9) | Reliability in insulating properties | Excellent | Good | Excellent | Good | Inferior | Inferior | Inferior |
| | (LS10, HAST, 3.3 V) | | | | | | | |
| (10) | Wrap of semiconductor | Excellent | Excellent | Excellent | Excellent | Inferior | Excellent | Inferior |

(Results)

It is clear from the results shown in Tables 4 and 5 that excellent results were obtained in the evaluations (2) to (10) in Examples 1 to 25. In other words, in Examples 1 to 25, the prepreg was excellent in low thermal expansion properties. The wiring board had preferable arithmetic mean roughness (Ra), no problems in appearance after PCT, and excellent embedability, peel strength, fine wiring workability, reliability in insulation properties, and low wrap. In addition, the semiconductor device also had low wrap.

In contrast, in Comparative Example 1, the prepreg was produced by infiltrating the second epoxy resin composition into the glass woven fabric. In other words, the prepreg in Comparative Example 1 did not contain the first resin layer, the core layer and the second resin layer, dissimilar to the prepreg in Examples 1 to 25. The results in the evaluations (2) to (10) were inferior to the evaluation results of Examples 1 to 25.

In Comparative Example 2, when preparing the first epoxy resin composition, the spherical silica having an average particle diameter of 1.0 μm was used instead of the silica nanoparticles having an average particle diameter of 1 to 100 nm. Therefore, the prepreg obtained had low thermal expansion properties, excellent embedability, peel strength, appearance after PCT, and low wrap properties, and the semiconductor also had low wrap properties. However, the arithmetic mean roughness, fine wiring workability, and reliability in insulation properties were inferior to the evaluation results of Examples 1 to 25.

In Comparative Example 3, when preparing the first epoxy resin composition, the silica nanoparticles having an average particle diameter of 1 to 100 nm was not used. Therefore, although the prepreg had excellent embeddability of the wiring board obtained, the results in the evaluations (3) to (10) were inferior to the evaluation results of Example 1 to 25.

### INDUSTRIAL APPLICABILITY

According to the present invention, it is possible to produce a prepreg which can be thinner, and has both surfaces which have different application, function, performance or properties to each other, one of which has excellent adhesion to the conductive layer, and the conductive layer which is in contact with the one surface of the prepreg can form a fine circuit.

In addition, another object of the present invention is to provide a wiring board including the prepreg, and a semiconductor device including the wiring board.

### REFERENCE SIGNS LIST

1: fibrous base
11: core layer
2: first resin layer
3: second resin layer
4a and 4b: carrier film
41: circuit layer
5: pad
6: filled via hole
7: through-hole
8: semiconductor element
81: bump
10, 10a, 10b, 10c, 10d, 10e, and 10f: prepreg
100: wiring board
101: core substrate
200: semiconductor device

1. A prepreg including a core layer containing a fibrous base, a first resin layer which is formed on one surface of the core layer, a second layer which is formed on the other surface of the core layer, and a carrier film which is selected from the group consisting of a metal foil and a resin film and which is laminated on at least one of the surfaces of the first resin layer and the second resin layer,
wherein the first resin layer contains a first epoxy resin composition containing silica nanoparticles having an average particle diameter of 1 to 100 nm; a thermoplastic resin selected from the group consisting of a polyimide resin, a polyamide resin, a phenoxy resin, a polyphenylene oxide resin, and a polyether sulfone resin; and an epoxy resin, and the first resin layer is in contact with the fibrous base or a part of the first resin layer is infiltrated into the fibrous base;
the second resin layer contains a second epoxy resin composition containing an inorganic filler, and an epoxy resin, and a part of the second resin layer is infiltrated into the fibrous base.

2. The prepreg according to claim 1, wherein the first epoxy resin composition contains 1 to 25% by weight of the silica nanoparticles having an average particle diameter of 1 to 100 nm.

3. The prepreg according to claim 1 or 2, wherein the surface roughness Ra of the surface of the first resin layer which is not in contact with the fibrous base is 0.8 μm or less.

4. The prepreg according to claim 1, wherein the average particle diameter of the inorganic filler in the second epoxy resin composition is in a range of 0.3 to 3 μm.

5. The prepreg according to claim 1, wherein the second epoxy resin composition further contains a cyanate resin.

6. The prepreg according to claim 1, wherein the first resin layer is thinner than the second resin layer.

7. The prepreg according to claim 1, wherein the percentage of the thickness of the first resin layer is 5% or more and less than 40% of the total thickness of the core layer, the first resin layer, and the second resin layer.

8. The prepreg according to claim 1, wherein the total thickness of the core layer, the first resin layer, and the second resin layer is 120 μm or less.

9. The prepreg according to claim 1, wherein the thickness of the fibrous base is 100 μm or less.

10. The prepreg according to claim 1, wherein the melt viscosity of the second epoxy resin composition constituting the second resin layer is in a range of 50 to 5,000 Pa·s.

11. The prepreg according to claim 1, wherein the first epoxy resin composition further contains spherical silica having an average particle diameter in a range of 0.1 to 2 μm.

12. A wiring board including the prepreg according to claim 1 which is laminated on a conductive circuit such that the second resin layer is in contact with the conductive circuit.

13. A semiconductor device including the wiring board according to claim 12.
